(19) United States
(12) Patent Application Publication
(10) Pub. No.: US 2026/0040799 A1
(43) Pub. Date: Feb. 5, 2026

(54) DISPLAY APPARATUS

(71) Applicant: LG Display Co., Ltd., Seoul (KR)

(72) Inventors: Jonghyun PARK, Paju-si (KR); Minho LEE, Paju-si (KR)

(73) Assignee: LG Display Co., Ltd., Seoul (KR)

(21) Appl. No.: 19/251,694

(22) Filed: Jun. 26, 2025

(30) Foreign Application Priority Data
Jul. 30, 2024 (KR) 10-2024-0100770

(51) Int. Cl. H10K 59/80; H10K 59/122; H10K 59/131

(52) U.S. Cl. CPC H10K 59/879; H10K 59/122; H10K 59/131; H10K 59/8792

(57) ABSTRACT

A display apparatus includes a substrate including a display area including first, second, and third pixels, each of which includes a plurality of sub-pixels, and a non-display area around the display area, a first microlens corresponding to each of the sub-pixels of the first pixel, a third microlens corresponding to each of the sub-pixels of the third pixel, a first light-blocking pattern on a surface of the first microlens, and a third light-blocking pattern on a surface of the third microlens, wherein each of the first and third microlenses includes a first part located at a first side with respect to a division line and a second part located at a second side opposite to the first side, the first light-blocking pattern is disposed on the first part of the first microlens, and the third light-blocking pattern is disposed on the second part of the third microlens.

### CROSS REFERENCE TO RELATED APPLICATION

The present application claims priority to Korean Patent Application No. 10-2024-0100770, filed Jul. 30, 2024, the entire contents of which is incorporated herein for all purposes by this reference.

### BACKGROUND

### Field of the Disclosure

The present disclosure relates to an apparatus and particularly to, for example, without limitation, a display apparatus.

### Description of the Related Art

As the information society develops, various demands for display apparatuses for displaying images are increasing, and various types of display apparatuses, such as a liquid crystal display (LCD) apparatus and an organic light emitting diode (OLED) display apparatus, are being utilized.

Among the display apparatuses, there is an advantage in that the OLED display apparatus as the self-luminous type has a wider viewing angle and a high contrast ratio, and is lighter and thinner and has less power consumption than the LCD apparatus because it does not require a separate backlight. In addition, there is an advantage in that the OLED display apparatus can drive at a low voltage, have a fast response time, and especially have the inexpensive manufacturing cost.

The description provided in the discussion of the related art section should not be assumed to be prior art merely because it is mentioned in or associated with that section. The discussion of the related art section may include information that describes one or more aspects of the subject technology, and the description in this section does not limit the disclosure.

### SUMMARY

The OLED display apparatus can also be applied to display apparatuses mounted on vehicles. The inventors of the present disclosure have recognized that among display apparatuses installed on a vehicle, display apparatuses in front of a driver's seat and a front passenger's seat need to limit a viewing angle of a driver according to driving situations of the driver. The display apparatus needs to limit a viewing angle according to a user's needs for privacy and information protection.

The present disclosure is directed to providing a display apparatus having a design with improved aesthetic feeling.

The present disclosure is also directed to providing a display apparatus capable of displaying different images according to a viewing angle.

The present disclosure is also directed to providing a display apparatus capable of differently providing an image that can be viewed by each of not only a driver sitting on a driver's seat and a front passenger sitting on a front passenger's seat but also a passenger sitting on a rear seat when a vehicle display is applied.

The present disclosure is also directed to providing a display apparatus in which it is possible to easily control a path of light emitted from a light-emitting part.

The present disclosure is also directed to providing a display apparatus in which it is possible to prevent or suppress a light leakage defect.

The present disclosure is also directed to providing a display apparatus in which it is possible to minimize or reduce a reduction in luminance of the display apparatus, thereby minimizing or reducing a reduction in luminous efficiency.

The present disclosure is also directed to providing a display apparatus in which it is possible to suppress or prevent crosstalk between different images when the different images are displayed according to a viewing angle.

Objects of the present disclosure are not limited to the above-described objects, and other technical objects may be inferred from the following example embodiments.

According to an example embodiment of the present disclosure, there is provided a display apparatus including a substrate including a display area including a first pixel, a second pixel, and a third pixel, each of which includes a plurality of sub-pixels, and a non-display area around the display area, a first microlens corresponding to each of the plurality of sub-pixels of the first pixel on the substrate, a third microlens corresponding to each of the plurality of sub-pixels of the third pixel on the substrate, a first light-blocking pattern on a surface of the first microlens, and a third light-blocking pattern on a surface of the third microlens, wherein each of the first microlens and the third microlens includes a first part located at a first side, and a second part located at a second side that is a side opposite to the first side with respect to a division line, the first light-blocking pattern is disposed on the first part of the first microlens, and the third light-blocking pattern is disposed on the second part of the third microlens.

According to another example embodiment of the present disclosure, there is provided a display apparatus including a substrate including a display area including a first pixel, a second pixel, and a third pixel, each of which includes a plurality of sub-pixels, and a non-display area around the display area, a thin film transistor disposed on the substrate, a protective layer disposed on the thin film transistor, a light-emitting part disposed on the protective layer and including an anode electrode, an organic layer, and a cathode electrode, an encapsulation layer disposed on the light-emitting part, a microlens disposed on the encapsulation layer and including a first microlens corresponding to the first pixel and a third microlens corresponding to the third pixel, and a light-blocking pattern including a first light-blocking pattern disposed on the first microlens and a third light-blocking pattern disposed on the third microlens, each of the first microlens and the third microlens includes a first part located at a first side with respect to a division line that divides the first microlens and the third microlens, and a second part located at a second side that is a side opposite to the first side, the first light-blocking pattern is disposed on the first part, and the third light-blocking pattern is disposed on the second part.

Detailed matters of other example embodiments are included in the detailed description and accompanying drawings.

According to example embodiments of the present disclosure, it is possible to provide the display apparatus with improved aesthetic feeling.

According to example embodiments of the present disclosure, it is possible to display different images according to a viewing angle.

According to example embodiments of the present disclosure, it is possible to differently provide an image that can be viewed by each of not only the driver sitting on the driver's seat and the front passenger sitting on the front passenger's seat but also the passenger sitting on the rear seat when the vehicle display is applied.

According to example embodiments of the present disclosure, it is possible to easily control the path of light emitted from the light-emitting part.

According to example embodiments of the present disclosure, it is possible to prevent or control a light leakage defect.

According to example embodiments of the present disclosure, it is possible to minimize or reduce a reduction in luminance of the display apparatus, thereby minimizing or reducing a reduction in luminous efficiency.

According to example embodiments of the present disclosure, it is possible to suppress or prevent crosstalk between different images when the different images are displayed according to the viewing angle.

According to example embodiments of the present disclosure, it is possible to suppress or prevent crosstalk between different images according to the viewing angle, thereby improving the quality of the image disposed on the display apparatus and reducing power consumption in response to the needs for relatively low power required to display the image.

However, effects obtainable from the present disclosure are not limited to the above-described effects, and other effects that are not mentioned will be able to be clearly understood by those skilled in the art to which the present disclosure pertains based on the following description.

It is to be understood that both the foregoing general description and the following detailed description of the present disclosure are by way of example and are intended to provide further explanation of the disclosures as claimed.

### BRIEF DESCRIPTION OF THE DRAWINGS

The accompanying drawings, which are included to provide a further understanding of the present disclosure and are incorporated in and constitute a part of this application, illustrate example embodiments of the present disclosure and together with the description serve to explain various principles of the disclosure.

FIG. 1 is a plan view of a display apparatus according to an example embodiment of the present disclosure.

FIG. 2 is an enlarged view of area Q1 in FIG. 1.

FIG. 3 is a view illustrating only a display panel of FIG. 2.

FIG. 4 is a plan view illustrating a pixel arrangement of a display panel according to an example embodiment of the present disclosure.

FIG. 5 is a cross-sectional view along line D-D′ in FIG. 4.

FIG. 6 is a cross-sectional view of a touch part of FIG. 5 taken at a different angle.

FIG. 7 is a cross-sectional view along line A-A′ in FIG. 1.

FIG. 8 is a cross-sectional view along line B-B′ in FIG. 3.

FIG. 9 is a cross-sectional view along line C-C′ in FIG. 3.

FIG. 10 is a schematic view illustrating a path of light emitted from the display panel according to an example embodiment of the present disclosure.

FIG. 11 is a graph illustrating luminance according to a viewing angle of the display apparatus according to an example embodiment of the present disclosure.

FIG. 12 is an enlarged view illustrating a pixel arrangement of a display panel according to another example embodiment of the present disclosure.

FIG. 13 is a cross-sectional view along line E-E′ in FIG. 12.

FIG. 14 is an enlarged view illustrating a pixel arrangement of a display panel according to still another example embodiment of the present disclosure.

FIG. 15 is a cross-sectional view along line F-F′ in FIG. 14.

FIG. 16 is an enlarged view illustrating a pixel arrangement of a display panel according to yet another example embodiment of the present disclosure.

FIG. 17 is a cross-sectional view along line G-G′ in FIG. 16.

FIG. 18 is an enlarged view illustrating a pixel arrangement of a display panel according to yet another example embodiment of the present disclosure.

FIG. 19 is a cross-sectional view along line H-H′ in FIG. 18.

FIG. 20 is a plan view of a display apparatus according to another example embodiment of the present disclosure.

FIG. 21 is an enlarged view of area Q2 in FIG. 20.

FIG. 22 is a cross-sectional view along line K-K′ in FIG. 21.

### DETAILED DESCRIPTION

Hereinafter, various example embodiments will be described with reference to the accompanying drawings. In the specification, where a first component (or an area, a layer, a portion, etc.) is described as “on,” “connected,” or “coupled to” a second component, it means that the first component may be directly connected/coupled to the second component or a third component may be disposed therebetween.

The same reference numerals indicate the same components. In addition, in the drawings, thicknesses, proportions, and dimensions of components are exaggerated for effective description of technical contents. The term “and/or” includes all one or more combinations that may be defined by the associated configurations.

Terms such as first and second may be used to describe various components, but the components are not limited by the terms. The terms are used only for the purpose of referring to one component separately from another. For example, a first component may be referred to as a second component, and similarly, the second component may also be referred to as the first component without departing from the scope of the present disclosure. Singular expressions include plural expressions, and vice versa, unless the context clearly states otherwise.

Terms such as “under,” “at a lower side,” “above,” and “at an upper side” are used to describe the relationship between the components illustrated in the drawings. The terms are relative concepts and are described with respect to directions marked in the drawings.

It should be understood that a term such as “includes” or “has” is intended to specify the presence of features, numbers, steps, operations, components, parts, or a combination thereof described in the specification and does not preclude the presence or addition possibility of one or more other features, numbers, steps, operations, components, parts, or combinations thereof in advance.

Any implementation described herein as an “example” is not necessarily to be construed as preferred or advantageous over other implementations.

In describing a temporal relationship, where the temporal order is described as, for example, “after,” “subsequent,” “next,” and “before,” a case that is not continuous may be included unless a more limiting term, such as “just,” “immediate(ly),” or “direct(ly),” is used.

The expression of a first element, a second elements, “and/or” a third element should be understood as one of the first, second and third elements or as any or all combinations of the first, second and third elements. By way of example, A, B and/or C can refer to only A; only B; only C; any or some combination of A, B, and C; or all of A, B, and C.

The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, or the third element.

Unless otherwise defined, all terms (including technical and scientific terms) used herein have the same meaning as commonly understood by one of ordinary skill in the art to which example embodiments belong. It should be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Advantages and features of the present disclosure and implementation methods thereof will be clarified through the following example embodiments described with reference to the accompanying drawings. The present disclosure may, however, be embodied in different forms and should not be construed as limited to the embodiments set forth herein. Rather, these example embodiments may be provided so that this disclosure may be sufficiently thorough and complete to assist those skilled in the art to fully understand the scope of the present disclosure.

Features of various embodiments of the present disclosure may be partially or overall coupled to or combined with each other, and may be variously inter-operated with each other and driven technically as those skilled in the art can sufficiently understand. Embodiments of the present disclosure may be carried out independently from each other, or may be carried out together in co-dependent relationship.

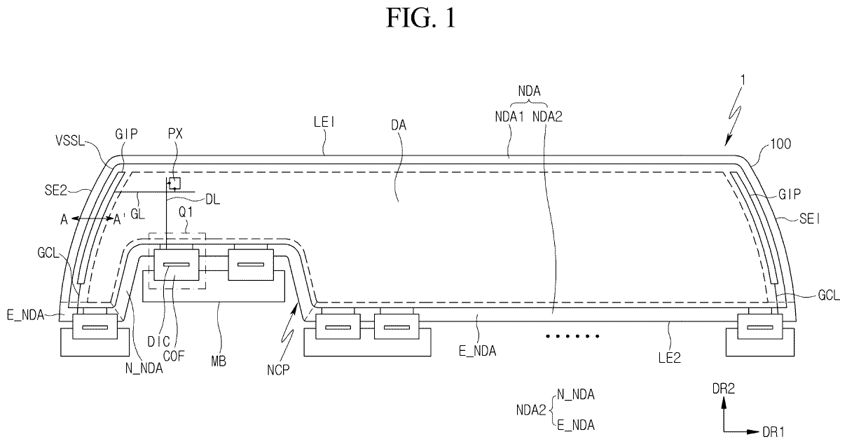

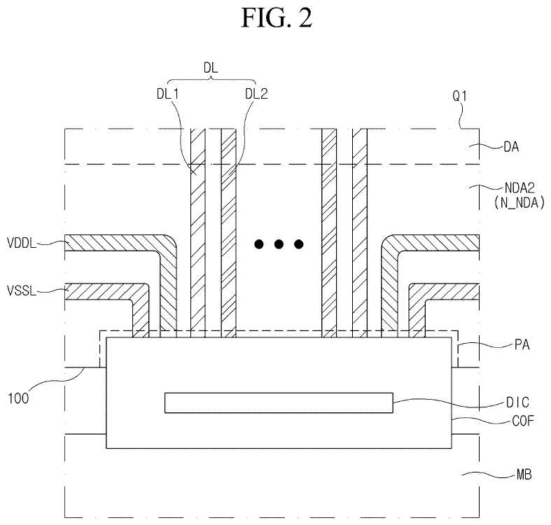

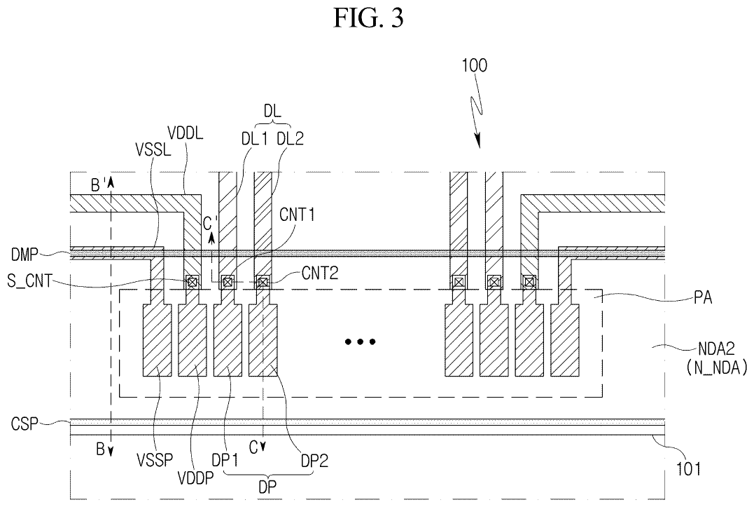

FIG. 1 is a plan view of a display apparatus according to an example embodiment of the present disclosure. FIG. 2 is an enlarged view of area Q1 in FIG. 1. FIG. 3 is a view illustrating only a display panel of FIG. 2.

FIG. 3 is a view of FIG. 2 from which a flexible film COF, a main board MB, and a drive IC DIC are omitted except for the display panel 100. In FIG. 3, for convenience of description, ratios between components are adjusted.

As shown in FIGS. 1 to 3, a display apparatus 1 may be an apparatus including both a display function for displaying a video and a touch sensing function for sensing touch of a user, but is not limited thereto. For example, the display apparatus 1 may include only one of the display function of displaying an image and the touch sensing function of sensing a user's touch.

The display apparatus 1 may be an electroluminescent display apparatus or a micro light-emitting diode display apparatus that includes a touch sensor. The electroluminescent display apparatus including the touch sensor may be an organic light-emitting diode (OLED) display apparatus, a quantum-dot light-emitting diode display apparatus, or an inorganic light-emitting diode display apparatus.

The display apparatus 1 according to the present example embodiment may be a vehicle display apparatus, but is not limited thereto. For example, the description of the display apparatus 1 may be applied without limitation to the type of the apparatus as long as a display apparatus is an apparatus including a display function.

When the display apparatus 1 according to the present example embodiment is a vehicle display apparatus, the display apparatus 1 may include a function of manipulating at least some of various functions of a vehicle, a function of displaying various pieces of information about the vehicle, etc.

When the display apparatus 1 according to the present example embodiment is a vehicle display apparatus, the display apparatus 1 may be disposed on a dashboard of a vehicle. The display apparatus 1 may be disposed across a driver's seat and a front passenger's seat that are disposed at front seats of a vehicle, but is not limited thereto.

All of a driver DRIVER sitting on a driver's seat, a passenger CO-DRIVER sitting on a front passenger's seat, and a passenger PASSENGER sitting on a rear seat may use the display apparatus 1.

The display apparatus 1 may provide different images to each of the driver DRIVER sitting on the driver's seat, the passenger CO-DRIVER sitting on the front passenger's seat, and the passenger PASSENGER sitting on the rear seat. However, the embodiments of the present disclosure are not limited thereto, and the display apparatus 1 may provide the same image to all of the driver DRIVER sitting on the driver's seat, the passenger CO-DRIVER sitting on the front passenger's seat, and the passenger PASSENGER sitting on the rear seat.

The display apparatus 1 may include a display panel 100. The display panel 100 may include a display area DA and a non-display area NDA.

The display area DA may be an area in which light is emitted to the outside to display a screen. The display area DA may further include a function of sensing a user's touch. In this case, the display area DA may correspond to a touch sensing area, but is not limited thereto.

The display area DA may correspond to the shape of the display panel 100, but is not limited thereto.

The display panel 100 may include a plurality of pixels PX. The plurality of pixels PX may be disposed in the display area DA. The plurality of pixels PX may be repeatedly disposed in a first direction DR1 and a second direction DR2.

The non-display area NDA may be an area in which light is not emitted to the outside so as not to display a screen. The non-display area NDA may be located around the display area DA. The non-display area NDA may surround the display area DA, but the embodiments of the present disclosure are not limited thereto. A bezel area of the display apparatus 1 may be defined by the non-display area NDA, but the embodiments of the present disclosure are not limited thereto.

The display panel 100 may be a rigid display panel, but is not limited thereto. The display panel 100 may be a flexible display panel of which shape may be deformed, such as a foldable, bendable, rollable, or stretchable display panel.

The display panel 100 may include a first long edge LE1, a second long edge LE2, a first short edge SE1, and a second short edge SE2 that form an edge of the display panel 100.

The first long edge LE1 and the second long edge LE2 may extend in a first direction DR1, and the first short edge SE1 and the second short edge SE2 may extend in a direction between the first direction DR1 and a second direction DR2. The first long edge LE1 and the second long edge LE2 may have both ends connected through the first short edge SE1 and the second short edge SE2.

The first long edge LE1 may be disposed at one side of the second long edge LE2 in the second direction DR2. The first long edge LE1 and the second long edge LE2 may extend in parallel, but are not limited thereto.

A length of the first long edge LE1 may be shorter than a length of the second long edge LE2. Accordingly, the first short edge SE1 and the second short edge SE2 may extend in an intersecting direction, but are not limited thereto.

The first direction DR1 and the second direction DR2 may be directions intersecting each other. The first direction DR1 and the second direction DR2 may be orthogonal, but are not limited thereto. The first direction DR1 and the second direction DR2 are provided to clarify the description of the disclosure, the first direction DR1 and the second direction DR2 are relative, and the embodiments of the present disclosure are not limited thereto.

In a plan view, the first long edge LE1 may be disposed above the display area DA, and the second long edge LE2 may be disposed under the display area DA.

In a plan view, the first short edge SE1 may be disposed at the right side of the display area DA, and the second short edge SE2 may be disposed at the left side of the display area DA.

The display panel 100 may include a curved notch NCP. The notch NCP may be formed at the second long edge LE2, but is not limited thereto. That is, the second long edge LE2 may entirely extend in the first direction DR1, but may include the notch NCP that is curved toward the first long edge LE1.

Since the notch NCP is disposed, components, such as a handle of a driver's seat, may be disposed on the corresponding portion to maximize or improve the display area DA capable of displaying the screen, thereby improving a user's convenience and improving aesthetic feeling.

The non-display area NDA may include a first non-display area NDA1 disposed along the first long edge LE1, the first short edge SE1, and the second short edge SE2, and a second non-display area NDA2 disposed along the second long edge LE2. The second non-display area NDA2 may be disposed along the second long edge LE2 including the curved notch NCP.

The first non-display area NDA1 may be disposed at one side and the other side of the display area DA in the first direction DR1 and disposed at one side of the display area DA in the second direction DR2.

The second non-display area NDA2 may include a notch non-display area N_NDA disposed around the notch NCP, and an extension non-display area E_NDA disposed around the notch non-display area N_NDA.

The extension non-display area E_NDA may extend from the notch non-display area N_NDA in the first direction DR1. The extension non-display area E_NDA may be disposed between the notch non-display area N_NDA and the first non-display area NDA1. The extension non-display area E_NDA may connect the notch non-display area N_NDA to the first non-display area NDA1.

The display apparatus 1 may further include a pad area PA, a gate driving unit GIP, a main board MB, a flexible film COF, a drive IC DIC, a gate line GL, a gate control line GCL, a data line DL, a low-potential voltage line VSSL, and a high-potential voltage line VDDL.

The pad area PA may overlap the flexible film COF. The pad area PA may be attached to the flexible film COF. That is, the display panel 100 and the flexible film COF may be attached through the pad area PA.

The pad area PA may be disposed in the non-display area NDA. The pad area PA may be disposed in the second non-display area NDA2. The pad area PA may be disposed in each of the notch non-display area N_NDA and the extension non-display area E_NDA.

The pad area PA may include a plurality of pads. The pad area PA may include a low-potential voltage pad VSSP, a high-potential voltage pad VDDP, a first data pad DP1, and a second data pad DP2. The low-potential voltage pad VSSP, the high-potential voltage pad VDDP, the first data pad DP1, and the second data pad DP2 may be disposed in the pad area PA.

However, the embodiments of the present disclosure are not limited thereto, and the pad area PA disposed in an area that overlaps the flexible films COF disposed at both ends among the flexible films COF disposed along the non-display area NDA may further include a gate control pad (not illustrated).

The gate driving unit GIP may be disposed in the non-display area NDA. The gate driving unit GIP may be disposed at least one of one side and the other side of the display area DA in the first direction DR1, but is not limited thereto. In a plan view, the gate driving unit GIP may be disposed at the left side and the other side of the display area DA.

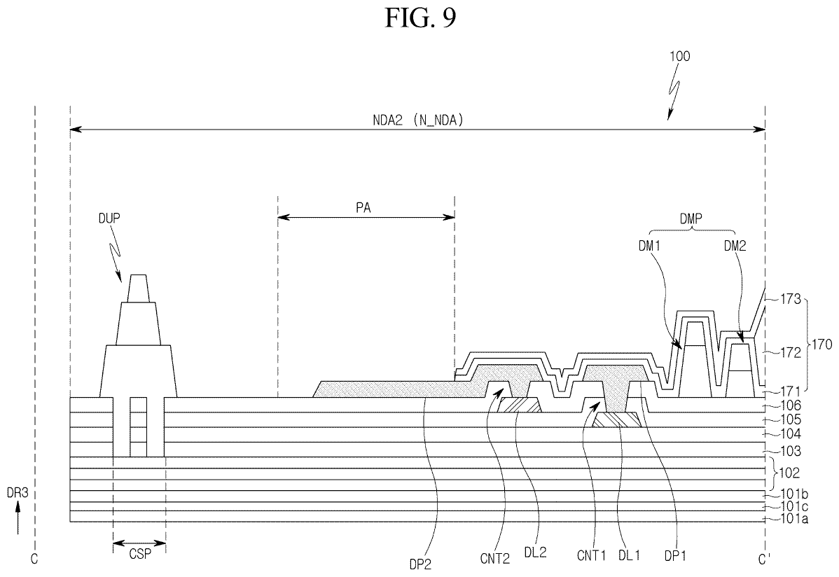

The gate driving unit GIP may include a plurality of transistors G120 (see FIG. 9). The transistors G120 (see FIG. 9) disposed in the gate driving unit GIP may be connected to a pixel PX through the gate line GL. The gate driving unit GIP may apply a gate signal to each pixel PX through the gate line GL.

The gate driving unit GIP may receive a gate control signal from the drive IC DIC through the gate control line GCL. The gate driving unit GIP may generate a scan signal and a light-emitting signal (or a light-emitting control signal) based on the gate control signal.

The gate driving unit GIP may include a scan driver and a light-emitting signal driver. The scan driver may generate a scan signal in a row-sequential manner and supply the scan signal to the scan lines to drive one or more scan lines connected to each pixel PX row. The light-emitting signal driver may generate a light-emitting signal in a row-sequential manner and supply the light-emitting signal to light-emitting signal lines to drive one or more light-emitting signal lines connected to each pixel PX row.

The main board MB may be connected to the display panel 100 through the flexible film COF. The main board MB may be electrically connected to the pixel PX of the display area DA through the flexible film COF. The main board MB may be electrically connected to the flexible film COF. The main board MB and the flexible film COF may be electrically connected through the plurality of pads VSSP, VDDP, and DP.

The main board MB may have various types of components for supplying various signals, such as a gate control signal, a driving signal, a data signal, etc., to the drive IC DIC. The main board MB may be a printed circuit board, but is not limited thereto.

The main board MB may be connected to the display panel 100 through the flexible film COF in the second non-display area NDA2. The main board MB may be provided as a plurality of main boards along the second non-display area NDA2, but is not limited thereto. The number of main boards MB may vary according to a design.

At least one of the main boards MB may be disposed around the notch NCP and connected to the display panel 100 through the flexible film COF in the notch non-display area N_NDA.

The flexible film COF may be connected to the display panel 100 and the main board MB. The flexible film COF may be attached to each of the display panel 100 and the main board MB and electrically connected to each of the display panel 100 and the main board MB. That is, the display panel 100 and the main board MB may be electrically connected through the flexible film COF. The flexible film COF may be provided as a plurality of flexible films, but is not limited thereto.

The flexible film COF may be attached to the display panel 100 in the second non-display area NDA2. The flexible film COF may be repeatedly disposed along the second non-display area NDA2. The flexible film COF may be attached to the display panel 100 across the notch non-display area N_NDA and the extension non-display area E_NDA.

A single main board MB may be electrically connected to the display panel 100 through at least one flexible film COF. For example, the main boards MB disposed at both ends among the plurality of main boards MB disposed along the second non-display area NDA2 may be electrically connected to the display panel 100 through one flexible film COF, and the remaining main boards MB may be electrically connected to the display panel 100 through two flexible films COF.

The flexible film COF may be electrically connected to the pad area PA. Accordingly, the flexible film COF may supply gate control signals, driving signals, power voltages, data voltages, and the like to the plurality of pixels PX and the gate driving unit GIP that are disposed in the display area DA.

The flexible film COF may be a flexible insulating film. The flexible film COF may include, for example, polycarbonate, polyethylene terephthalate, polyimide, polyamide, polyester, polyacrylate, polymethyl methacrylate, etc., but is not limited thereto.

The drive IC DIC may be mounted on the flexible film COF. The drive IC DIC may be disposed by a method of a chip on glass, a chip on film, a tape carrier package, etc. according to a mounting method. In the present disclosure, the drive IC DIC is described as being mounted on the flexible film COF by the chip on film method, but is not limited thereto.

The drive IC DIC may drive the display apparatus 1. The drive IC DIC may process data signals for displaying an image, various driving signals for processing the data signals, etc. The drive IC DIC may include a gate driver IC, a data driver IC, etc.

The gate line GL may be extended from the gate driving unit GIP and connected to the pixel PX. The gate line GL may electrically connect the gate driving unit GIP and the pixel PX. The gate line GL may apply the gate signal from the gate driving unit GIP to each pixel PX.

The gate control line GCL may be disposed in the non-display area NDA. The gate control line GCL may extend from the pad area PA to the gate driving unit GIP and may be electrically connected to the gate driving unit GIP.

The gate control line GCL may apply the gate control signal to the gate driving unit GIP. The gate control signal may be transmitted from the main board MB or the drive IC DIC. The gate control line GCL may electrically connect the gate driving unit GIP to the main board MB or the drive IC DIC.

The gate control line GCL may be electrically connected to the flexible film COF disposed at both ends among the plurality of flexible films COF connected to the display panel 100 along the second non-display area NDA2. The gate control line GCL may be disposed at an outermost edge among a plurality of lines connected to one flexible film COF, but is not limited thereto.

The data line DL may extend from the pad area PA and may be connected to the pixel PX of the display area DA. The data line DL may apply the data signal to each pixel PX. The data signal may be applied from the main board MB or the drive IC DIC. The data line DL may electrically connect the pixel PX to the main board MB or the drive IC DIC.

The data line DL may include a first data line DL1 and a second data line DL2. The data line DL may be connected to the data pads DP1 and DP2. The first data line DL1 may be electrically connected in contact with the first data pad DP1 through a first data contact hole CNT1. The second data line DL2 may be electrically connected in contact with the second data pad DP2 through a second data contact hole CNT2.

The low-potential voltage line VSSL may be disposed in the non-display area NDA to surround the display area DA. The low-potential voltage line VSSL may be disposed in the non-display area NDA with the display area DA and the gate driving unit GIP interposed therebetween. That is, the gate driving unit GIP may be disposed between the display area DA and the low-potential voltage line VSSL.

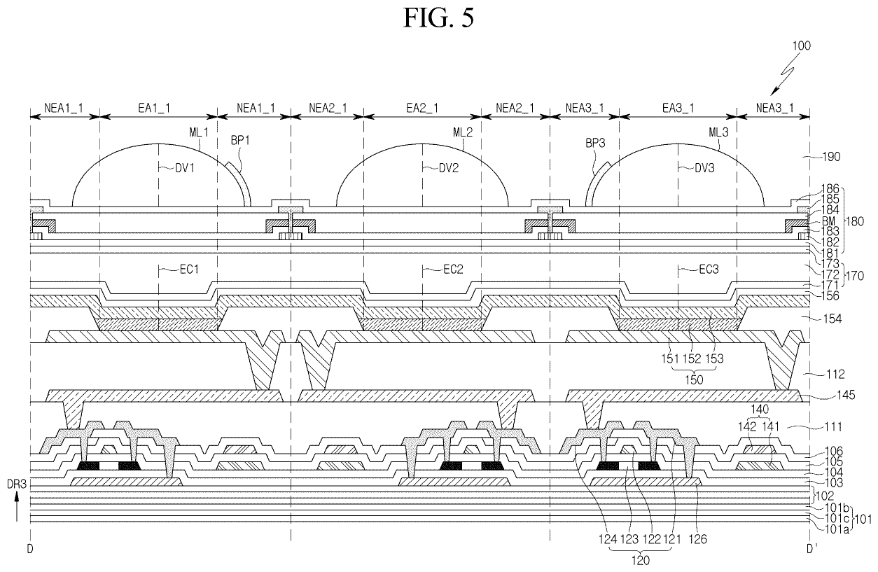

The low-potential voltage line VSSL may apply a low-potential voltage to the pixel PX. The low-potential voltage line VSSL may be electrically connected to a cathode electrode 153 (see FIG. 5) of the pixel PX to apply a low-potential voltage.

The low-potential voltage line VSSL may be connected to the pad area PA. The low-potential voltage line VSSL may be physically connected to the low-potential voltage pad VSSP and electrically connected to the low-potential voltage pad VSSP. The low-potential voltage line VSSL and the low-potential voltage pad VSSP may be formed integrally, but are not limited thereto.

The high-potential voltage line VDDL may be disposed between the display area DA and the low-potential voltage line VSSL. The high-potential voltage line VDDL may apply a high-potential voltage to the pixel PX. The high-potential voltage line VDDL may be electrically connected to an anode electrode 151 (see FIG. 5) of the pixel PX to apply a high-potential voltage.

The high-potential voltage line VDDL may be connected to the pad area PA. The high-potential voltage line VDDL may be physically connected to the high-potential voltage pad VDDP and electrically connected to the high-potential voltage pad VDDP. The high-potential voltage line VDDL may come into contact with the high-potential voltage pad VDDP by a high-potential contact hole S_CNT.

However, the embodiments of the present disclosure are not limited thereto, and the high-potential voltage line VDDL and the high-potential voltage pad VDDP may be formed integrally. For example, the high-potential voltage line VDDL may be formed of the same material and the same conductive layer as the high-potential voltage pad VDDP, and the high-potential voltage line VDDL and the high-potential voltage pad VDDP are formed together by the same mask process.

The display apparatus 1 may further include a dam part DMP. The dam part DMP may be disposed in the non-display area NDA. The dam part DMP may be disposed to surround the display area DA, but is not limited thereto. At least a part of the dam part DMP may be disposed to overlap the low-potential voltage line VSSL. The dam part DMP may be disposed between the display area DA and the pad area PA in the second non-display area NDA2.

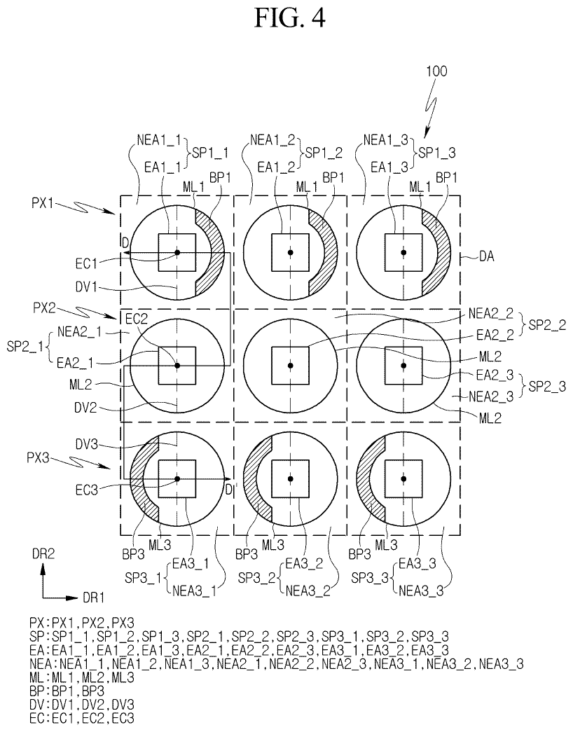

FIG. 4 is an enlarged view illustrating a pixel arrangement of a display panel according to an example embodiment of the present disclosure. The plan view of FIG. 4 is an enlarged view illustrating a part of the flat surface structure of the display area DA in which the pixels PX are disposed.

As shown in FIG. 4, the display panel 100 may include a first pixel PX1, a second pixel PX2, and a third pixel PX3. The first pixel PX1, the second pixel PX2, and the third pixel PX3 may be disposed in the display area DA.

Each of the first pixel PX1, the second pixel PX2, and the third pixel PX3 may be disposed repeatedly in the first direction DR1. The first pixel PX1, the second pixel PX2, and the third pixel PX3 may be alternately and repeatedly disposed in the second direction DR2. In the second direction DR2, the second pixel PX2 may be disposed between the first pixel PX1 and the third pixel PX3.

Each of the pixels PX1, PX2, and PX3 may include sub-pixels SP1_1, SP1_2, SP1_3, SP2_1, SP2_2, SP2_3, SP3_1, SP3_2, and SP3_3.

The first pixel PX1 may include a 1_1 sub-pixel SP1_1, a 1_2 sub-pixel SP1_2, and a 1_3 sub-pixel SP1_3. The 1_1 sub-pixel SP1_1, the 1_2 sub-pixel SP1_2, and the 1_3 sub-pixel SP1_3 may be disposed in a row in the first direction.

The 1_1 sub-pixel SP1_1 may emit red (R) light, the 1_2 sub-pixel SP1_2 may emit green (G) light, and the 1_3 sub-pixel SP1_3 may emit blue (B) light.

The 1-1 sub-pixel SP1_1, the 1_2 sub-pixel SP1_2, and the 1_3 sub-pixel SP1_3 may include light-emitting areas EA1_1, EA1_2, and EA1_3, and non-light-emitting areas NEA1_1, NEA1_2, and NEA1_3 disposed around the light-emitting areas EA1_1, EA1_2, and EA1_3, respectively.

The 1_1 sub-pixel SP1_1 may include a 1_1 light-emitting area EA1_1, and a 1_1 non-light-emitting area NEA1_1 disposed around the 1_1 light-emitting area EA1_1.

The 1_2 sub-pixel SP1_2 may include a 1_2 light-emitting area EA1_2, and a 1_2 non-light-emitting area NEA1_2 disposed around the 1_2 light-emitting area EA1_2.

The 1_3 sub-pixel SP1_3 may include a 1_3 light-emitting area EA1_3, and a 1_3 non-light-emitting area NEA1_3 disposed around the 1_3 light-emitting area EA1_3.

The second pixel PX2 may include a 2_1 sub-pixel SP2_1, a 2_2 sub-pixel SP2_2, and a 2_3 sub-pixel SP2_3. The 2_1 sub-pixel SP2_1, the 2_2 sub-pixel SP2_2, and the 2_3 sub-pixel SP2_3 may be disposed in a row in the first direction DR1.

The 2_1 sub-pixel SP2_1 may emit red (R) light, the 2_2 sub-pixel SP2_2 may emit green (G) light, and the 2_3 sub-pixel SP2_3 may emit blue (B) light.

The 2-1 sub-pixel SP2_1, the 2_2 sub-pixel SP2_2, and the 2_3 sub-pixel SP2_3 may include light-emitting areas EA2_1, EA2_2, and EA2_3, and non-light-emitting areas NEA2_1, NEA2_2, and NEA2_3 disposed around the light-emitting areas EA2_1, EA2_2, and EA2_3.

The 2_1 sub-pixel SP2_1 may include a 2_1 light-emitting area EA2_1, and a 2_1 non-light-emitting area NEA2_1 disposed around the 2_1 light-emitting area EA2_1.

The 2_2 sub-pixel SP2_2 may include a 2_2 light-emitting area EA2_2, and a 2_2 non-light-emitting area NEA2_2 disposed around the 2_2 light-emitting area EA2_2.

The 2_3 sub-pixel SP2_3 may include a 2_3 light-emitting area EA2_3, and a 2_3 non-light-emitting area NEA2_3 disposed around the 2_3 light-emitting area EA2_3.

The third pixel PX3 may include a 3_1 sub-pixel SP3_1, a 3_2 sub-pixel SP3_2, and a 3_3 sub-pixel SP3_3. The 3_1 sub-pixel SP3_1, the 3_2 sub-pixel SP3_2, and the 3_3 sub-pixel SP3_3 may be disposed in a row in the first direction DR1.

The 3_1 sub-pixel SP3_1 may emit red (R) light, the 3_2 sub-pixel SP3_2 may emit green (G) light, and the 3_3 sub-pixel SP3_3 may emit blue (B) light.

The 3-1 sub-pixel SP3_1, the 3_2 sub-pixel SP3_2, and the 3_3 sub-pixel SP3_3 may include light-emitting areas EA3_1, EA3_2, and EA3_3, and non-light-emitting areas NEA3_1, NEA3_2, and NEA3_3 disposed around the light-emitting areas EA3_1, EA3_2, and EA3_3, respectively.

The 3_1 sub-pixel SP3_1 may include a 3_1 light-emitting area EA3_1, and a 3_1 non-light-emitting area NEA3_1 disposed around the 3_1 light-emitting area EA3_1.

The 3_2 sub-pixel SP3_2 may include a 3_2 light-emitting area EA3_2, and a 3_2 non-light-emitting area NEA3_2 disposed around the 3_2 light-emitting area EA3_2.

The 3_3 sub-pixel SP3_3 may include a 3_3 light-emitting area EA3_3, and a 3_3 non-light-emitting area NEA3_3 disposed around the 3_3 light-emitting area EA3_3.

A microlens ML (ML1, ML2, and ML3) may be disposed on the pixels PX1, PX2, and PX3, respectively. A first microlens ML1 may be disposed on the first pixel PX1, a second microlens ML2 may be disposed on the second pixel PX2, and a third microlens ML3 may be disposed on the third pixel PX3.

The microlens ML may be disposed on the sub-pixel SP.

A first microlens ML1 may be disposed on the first pixel PX1 and disposed on each of the 1_1 sub-pixel SP1_1, the 1_2 sub-pixel SP1_2, and the 1_3 sub-pixel SP1_3.

A second microlens ML2 may be disposed on the second pixel PX2 and disposed on each of the 2_1 sub-pixel SP2_1, the 2_2 sub-pixel SP2_2, and the 2_3 sub-pixel SP2_3.

A third microlens ML3 may be disposed on the third pixel PX3 and disposed on each of the 3_1 sub-pixel SP3_1, the 3_2 sub-pixel SP3_2, and the 3_3 sub-pixel SP3_3.

Each microlens ML1, ML2, or ML3 may control a path of light emitted from each pixel PX1, PX2, or PX3. Each microlens ML1, ML2, or ML3 may adjust the path of the light emitted from each pixel PX1, PX2, or PX3 in a different direction.

For example, the first microlens ML1 may adjust the light emitted from the first pixel PX1 to travel toward the other side in the first direction DR1 in a plan view, the second microlens ML2 may condense the light emitted from the second pixel PX2 and adjust the light to travel in a thickness direction, and the third microlens ML3 may adjust the light emitted from the third pixel PX3 to travel toward the other side in the first direction DR1 in a plan view.

Accordingly, each pixel PX1, PX2, or PX3 may display a different image and video, and the display apparatus 1 (see FIG. 1) may display three different images and videos according to a viewing angle.

When the display apparatus 1 (see FIG. 1) is used for a vehicle, a screen displayed to the driver DRIVER sitting on the driver's seat and a screen displayed to the passenger CO-DRIVER sitting on the front passenger's seat and the passenger PASSENGER sitting on the rear seat may be distinctly controlled separately, and different screens may be displayed to the driver DRIVER and the passengers CO-DRIVER and PASSENGER.

However, the embodiments of the present disclosure are not limited thereto, and one of the pixels PX1, PX2, and PX3 may provide a screen displayed to all of the driver DRIVER and the passengers CO-DRIVER and PASSENGER. For example, a light-blocking pattern BP may not be disposed on the second pixel PX2, and the second pixel PX2 may provide a separate image and video only to the passenger PASSENGER sitting on the rear seat or provide the same image and video to all of the driver DRIVER and the passengers CO-DRIVER and PASSENGER.

The light-blocking pattern BP (BP1 and BP3) may be disposed on the microlens ML. The light-blocking pattern BP (BP1 and BP3) may include a first light-blocking pattern BP1 and a third light-blocking pattern BP3. The first light-blocking pattern BP may be disposed on the first microlens ML1, and the third light-blocking pattern BP3 may be disposed on the third microlens ML3. The first light-blocking pattern BP may be disposed on each of the first microlenses ML1, and the third light-blocking pattern BP3 may be disposed on each of the third microlenses ML3.

The light-blocking pattern BP may not be disposed on the second microlens ML2, but is not limited thereto.

The light-blocking pattern BP may include a material capable of absorbing and blocking light. For example, the light-blocking pattern BP may include a black pigment and/or dye, but is not limited thereto.

The light-blocking pattern BP may block the path of some of the light emitted from a light-emitting part 150 (see FIG. 5). Accordingly, each pixel PX1, PX2, or PX3 may display a different image, and a user may receive different images and videos according to a viewing angle.

The light-blocking pattern BP may be disposed in the non-light-emitting area NEA, but is not limited thereto, and some of the light-blocking patterns BP may be disposed to extend to the light-emitting area EA.

A first light-blocking pattern BP1 and the third light-blocking pattern BP3 may be disposed at different locations on the microlens ML. The first light-blocking pattern BP1 may be disposed on one side of the first microlens ML1 in the first direction DR1, and the third light-blocking pattern BP3 may be disposed at the other side of the third microlens ML3 in the first direction DR1.

The microlens ML may include a division line DV (DV1, DV2, and DV3). The division line DV may include a first division line DV1, a second division line DV2, and a third division line DV3.

The division line DV may refer to a virtual line that divides the microlens ML. The microlens ML may be divided into two substantially equal parts through the division line DV, but is not limited thereto. The two parts of the microlens ML divided by the division line DV may include a symmetrical shape, but is not limited thereto, and the two parts of the microlens ML divided by the division line DV may have different shapes and sizes.

In a plan view such as FIG. 4, the division line DV may pass the center EC (EC1, EC2, and EC3) of the light-emitting area EA, but is not limited thereto.

A first center EC1 may refer to the center of each of the light-emitting areas EA1_1, EA1_2, and EA1_3 of the sub-pixels SP1_1, SP1_2, and SP1_3 of the first pixel PX1.

A second center EC2 may refer to the center of each of the light-emitting areas EA2_1, EA2_2, and EA2_3 of the sub-pixels SP2_1, SP2_2, and SP2_3 of the second pixel PX2.

A third center EC3 may refer to the center of each of the light-emitting areas EA3_1, EA3_2, and EA3_3 of the sub-pixels SP3_1, SP3_2, and SP3_3 of the third pixel PX3.

The first microlens ML1 may include the first division line DV1, the second microlens ML2 may include the second division line DV2, and the third microlens ML3 may include the third division line DV3.

Each division line DV1, DV2, or DV3 may extend in the second direction DR2 in a plan view as in FIG. 4 and have a thickness in a thickness direction (a third direction DR3). Each division line DV1, DV2, or DV3 may be substantially the same, but is not limited thereto, and the flat surface shape of each division line DV1, DV2, or DV3 may vary according to the shape of each microlens ML1, ML2, or ML3.

Each microlens ML1, ML2, or ML3 may be divided into two parts (a first part and a second part) according to each division line DV1, DV2, or DV3. The first part and the second part of each microlens ML1, ML2, or ML3 may be disposed at one side and the other side of each division line DV1, DV2, or DV3 in the first direction DR1, respectively.

The first light-blocking pattern BP1 and the third light-blocking pattern BP3 may be disposed on two different parts of the microlenses ML1 and ML3 divided by the division lines DV1 and DV3. For example, the first light-blocking pattern BP1 may be disposed on a first part of the first microlens ML1 located at one side (or a first side) of the first division line DV1 in the first direction DR1 among the two parts of the first microlens ML1 divided by the first division line DV1, and the third light-blocking pattern BP3 may be disposed on a second part of the third microlens ML3 located at the other side (or a second side) of the third division line DV3 in the first direction DR1 among the two parts of the third microlens ML3 divided by the third division line DV3.

The first light-blocking pattern BP1 may block some of the light emitted from the first pixel PX1, which travel toward one side in the first direction DR1 in a plan view, and the third light-blocking pattern BP3 may block some of the light emitted from the third pixel PX3, which travel toward the other side in the first direction DR1 in a plan view.

Since the light-blocking pattern BP and the microlens ML are disposed, the path of the light emitted from the display panel 100 can be more easily controlled, and a light leakage defect that may occur between the pixels PX can be prevented or reduced. Accordingly, even when the first pixel PX1, the second pixel PX2, and the third pixel PX3 display different screens, it is possible to suppress or prevent crosstalk that may occur between images and videos displayed on each pixel PX1, PX2, or PX3. In addition, it is possible to improve the quality of images and videos displayed on each pixel PX1, PX2, or PX3 and minimize or reduce a reduction in luminance of the display apparatus 1 (see FIG. 1), thereby minimizing or reducing a reduction in luminous efficiency.

One microlens ML is illustrated as being disposed in each sub-pixel SP, but the embodiments of the present disclosure are not limited thereto. For example, according to a design of each sub-pixel SP, the microlens ML disposed on each sub-pixel SP may be provided as two or more microlenses. When an opening (the light-emitting area EA) formed in one sub-pixel SP is provided as a plurality of openings, the microlens ML may be disposed in each opening, or a plurality of microlenses ML may be disposed in one opening.

Hereinafter, a cross-sectional structure of the display area DA of the display panel 100 including the pixels PX will be described with reference to FIG. 5.

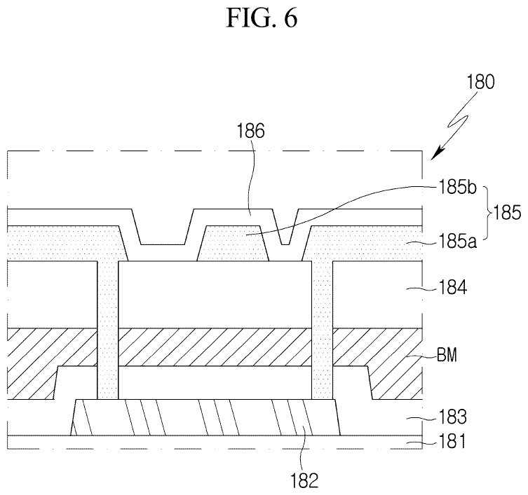

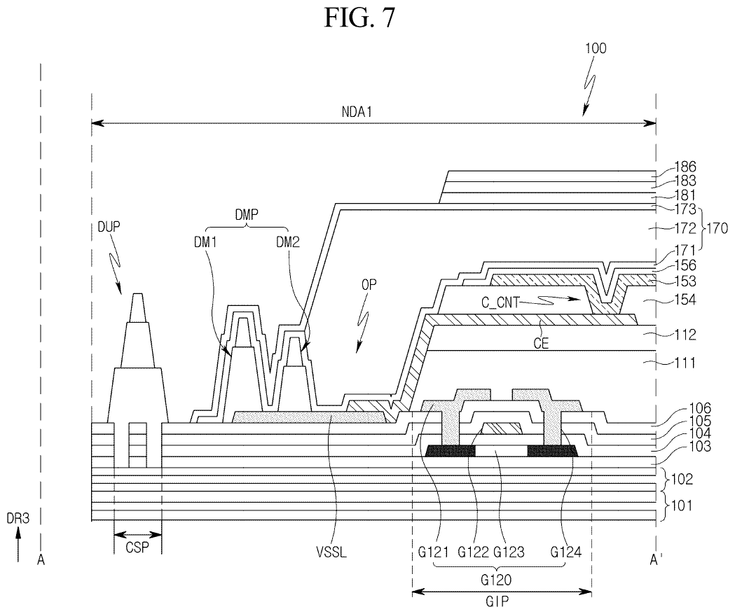

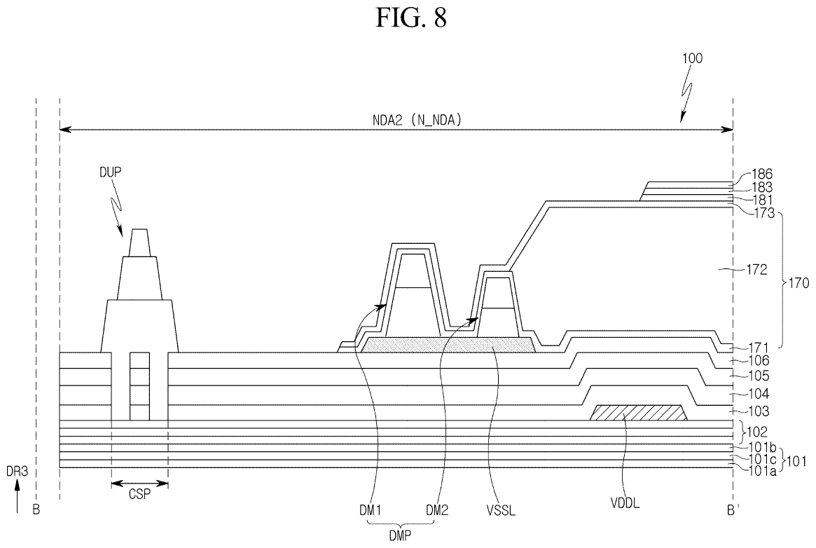

FIG. 5 is a cross-sectional view along line D-D′ in FIG. 4. FIG. 6 is a cross-sectional view of a touch part of FIG. 5 taken at a different angle. FIG. 7 is a cross-sectional view along line A-A′ in FIG. 1. FIG. 8 is a cross-sectional view along line B-B′ in FIG. 3. FIG. 9 is a cross-sectional view along line C-C′ in FIG. 3.

FIG. 7 illustrates a cross-sectional structure of the first non-display area NDA1. FIGS. 8 and 9 illustrate cross-sectional structures of the second non-display area NDA2. The descriptions of FIGS. 8 and 9 may also be applied to the extension non-display area E_NDA in substantially the same manner.

First, a cross section of the display area DA will be described with reference to FIGS. 4 to 6.

The display panel 100 may include a substrate 101, a thin film transistor 120, a storage electrode 140, an light-emitting part 150, an encapsulation part 170, and a touch part 180 in the display area DA. However, the embodiments of the present disclosure are not limited thereto.

The substrate 101 may provide a space in which various components may be disposed thereon. The substrate 101 may correspond to the flat surface shape of the display panel 100 of FIG. 1. That is, the substrate 101 may include the notch NCP. The substrate 101 may include the display area DA and the non-display area NDA of the display panel 100 in substantially the same manner.

The substrate 101 may include one or more plastic materials, but is not limited thereto, and may include a glass material.

The substrate 101 may be a multi-substrate including a plurality of substrates of a first substrate 101a, a second substrate 101b, and a third substrate 103c each including a plastic material, such as polyimide, but the embodiments of the present disclosure are not limited thereto. For example, the substrate 101 may be a single substrate formed of a single layer.

The substrate 101 may include a rigid substrate. However, the embodiments of the present disclosure are not limited thereto, and the substrate 101 may include a flexible substrate.

A buffer layer 102 may be disposed on the substrate 101. The buffer layer 102 can minimize or delay the diffusion of moisture or oxygen penetrating the substrate 101. The buffer layer 102 may be formed by alternately stacking silicon nitride (SiNx) and silicon oxide (SiOx) at least once, but the embodiments of the present disclosure are not limited thereto.

The disclosure describes that the buffer layer 102 is formed as multiple layers formed of three layers, but the number of layers forming the buffer layer 102 is not limited thereto, and the buffer layer 102 may be formed as a single layer.

A light-blocking layer 126 may be disposed on the buffer layer 102. The light-blocking layer 126 can prevent or reduce light from being transmitted to a semiconductor layer 123 of the thin film transistor 120. For example, the semiconductor layer 123 may be disposed to overlap the light-blocking layer 126. The light-blocking layer 126 may be formed of a single layer or multiple layers formed of one of molybdenum (Mo), aluminum (Al), chromium (Cr), nickel (Ni), neodymium (Nd), and copper (Cu) or an alloy thereof, but the embodiments of the present disclosure are not limited thereto.

A first insulating layer 103 may be disposed on the light-blocking layer 126. The first insulating layer 103 can prevent a short circuit between a component of the thin film transistor 120 and the light-blocking layer 126. The first insulating layer 103 may be formed of the same material as the buffer layer 102, but the embodiments of the present disclosure are not limited thereto. For example, the first insulating layer 103 may be formed of an inorganic material, such as silicon nitride (SiNx) or silicon oxide (SiOx), but the embodiments of the present disclosure are not limited thereto.

The thin film transistor 120 may be disposed on the first insulating layer 103. The thin film transistor 120 may include the source electrode 121, a gate electrode 122, a semiconductor layer 123, and a drain electrode 124.

The semiconductor layer 123 may be disposed on the first insulating layer 103. The semiconductor layer 123 may include a metal oxide semiconductor, such as indium-gallium-zinc oxide (IGZO), and a silicon-based semiconductor material, such as amorphous silicon or polycrystalline silicon, but the embodiments of the present disclosure are not limited thereto. The semiconductor layer 123 may include a source area, a drain area, and a channel area between the source area and the drain area.

Since the polycrystalline semiconductor layer has higher mobility than the amorphous semiconductor layer and the oxide semiconductor layer, power consumption can be less, and reliability can be excellent. Accordingly, a driving transistor may be formed of a polycrystalline semiconductor layer, but the embodiments of the present disclosure are not limited thereto.

A second insulating layer 104 may be disposed on the semiconductor layer 123. The second insulating layer 104 may be formed of the same material as the first insulating layer 103, but the embodiments of the present disclosure are not limited thereto. The second insulating layer 104 can prevent a short circuit between the semiconductor layer 123 and another component of the thin film transistor 120.

The gate electrode 122 may be disposed on the second insulating layer 104. The gate electrode 122 may be disposed on the second insulating layer 104 to overlap the channel area of the semiconductor layer 123. The gate electrode 122 may be formed of a single layer or multiple layers made of molybdenum (Mo), copper (Cu), titanium (Ti), aluminum (Al), chromium (Cr), gold (Au), nickel (Ni), neodymium (Nd), or a compound thereof, but the embodiments of the present disclosure are not limited thereto. The gate electrode 122 may be disposed along with the gate line, but the embodiments of the present disclosure are not limited thereto.

A third insulating layer 105 may be disposed on the gate electrode 122. The third insulating layer 105 may be formed of the same material as the first insulating layer 103 or the second insulating layer 104, but the embodiments of the present disclosure are not limited thereto.

The storage electrode 140 may be disposed to be spaced apart from the thin film transistor 120. The storage electrode 140 may include a first storage electrode 141 and a second storage electrode 142.

The first storage electrode 141 may be formed of the same material as the gate electrode 122 and formed on the same layer, but the embodiments of the present disclosure are not limited thereto.

The second storage electrode 142 may be disposed on the first storage electrode 141. The second storage electrode 142 may be disposed on the third insulating layer 105, and the third insulating layer 105 between the first storage electrode 141 and the second storage electrode 142 may be used as a dielectric to generate a capacitance. The second storage electrode 142 may be formed of the same material as the first storage electrode 141, but the embodiments of the present disclosure are not limited thereto.

A fourth insulating layer 106 may be disposed on the second storage electrode 142. The fourth insulating layer 106 may be formed of the same material as the first insulating layer 103, the second insulating layer 104, or the third insulating layer 105, but the embodiments of the present disclosure are not limited thereto.

The source electrode 121 and the drain electrode 124 may be disposed on the fourth insulating layer 106.

The source electrode 121 and the drain electrode 124 may be electrically connected to the semiconductor layer 123 through contact holes. The source electrode 121 and the drain electrode 124 may be formed of a metallic material. For example, the source electrode 121 and the drain electrode 124 may be formed of a single layer or multiple layers made of one of molybdenum (Mo), aluminum (Al), chromium (Cr), gold (Au), titanium (Ti), nickel (Ni), neodymium (Nd), and copper (Cu) or an alloy thereof, but the embodiments of the present disclosure are not limited thereto.

The source electrode 121 and the drain electrode 124 may be disposed along with the data line. For example, the data line may be formed of the same material as the source electrode 121 and the drain electrode 124 and formed on the same layer, but the embodiments of the present disclosure are not limited thereto.

The thin film transistor 120 may be a driving transistor, and although not illustrated, the display panel 100 may further include a switching transistor, but the embodiments of the present disclosure are not limited thereto.

A first protective layer 111 may be disposed on the source electrode 121 and the drain electrode 124.

The first protective layer 111 may planarize an upper portion of the thin film transistor 120 and protect the thin film transistor 120. The first protective layer 111 may be formed of an organic material. For example, the first protective layer 111 may be formed of an organic material including an acrylic resin, an epoxy resin, a phenolic resin, a polyamide resin, or a polyimide resin, but the embodiments of the present disclosure are not limited thereto.

A second protective layer 112 may be disposed on the first protective layer 111. The second protective layer 112 may be formed of the same material as the first protective layer 111, but the embodiments of the present disclosure are not limited thereto.

A connection electrode 145 may be disposed between the first protective layer 111 and the second protective layer 112.

The connection electrode 145 may electrically connect the thin film transistor 120 to the light-emitting part 150. The connection electrode 145 may be formed of the same material as the source electrode 121 and the drain electrode 124, but the embodiments of the present disclosure are not limited thereto.

The connection electrode 145 may come into contact with the drain electrode 124 through the contact hole formed in the first protective layer 111 and may be electrically connected to the drain electrode 124.

The connection electrode 145 may be formed of a single layer or multiple layers made of any one of molybdenum (Mo), aluminum (Al), chromium (Cr), gold (Au), titanium (Ti), nickel (Ni), neodymium (Nd), and copper (Cu) or an alloy thereof, but the embodiments of the present disclosure are not limited thereto.

The light-emitting part 150 may be disposed on the second protective layer 112. The light-emitting part 150 may include the anode electrode 151, an organic layer 152, and the cathode electrode 153.

The anode electrode 151 may be disposed on the second protective layer 112. The anode electrode 151 may be electrically connected to the thin film transistor 120 through a contact hole formed in the second protective layer 112.

The anode electrode 151 may be a reflective electrode that reflects light, but the embodiments of the present disclosure are not limited thereto. The anode electrode 151 may include a metallic material with high reflectivity, such as a stacking structure (Ti/Al/Ti) of aluminum (Al) and titanium (Ti), a stacking structure (ITO/Al/ITO) of aluminum (Al) and indium tin oxide (ITO), or an APC alloy and may be formed of a single layer or multiple layers, but the embodiments of the present disclosure are not limited thereto.

For example, the cathode electrode 153 may include a material, such as indium tin oxide (ITO) or indium zinc oxide (IZO), but the embodiments of the present disclosure are not limited thereto.

The organic layer 152 may be disposed on the anode electrode 151. The organic layer 152 may include one or more light-emitting structures (or light-emitting elements or elements) stacked on the anode electrode 151 in the order or reverse order of a hole transfer layer and an electron transfer layer. For example, the hole transfer layer may include a hole transporting layer, a hole injecting layer, an electron blocking layer, a p-type charge generation layer, etc., but the embodiments of the present disclosure are not limited thereto. For example, the electron transfer layer may include an electron transporting layer, an electron injecting layer, a hole blocking layer, an n-type charge generation layer, etc., but the embodiments of the present disclosure are not limited thereto.

The organic layer 152 may be an organic light-emitting layer, an inorganic light-emitting layer, a quantum dot light-emitting layer, a micro light-emitting diode, a micro mini light-emitting diode, etc., but the embodiments of the present disclosure area not limited thereto. For example, the organic layer 152 of the display panel 100 according to an example embodiment of the present disclosure may include an organic light-emitting layer. The organic layer 152 may be a white light-emitting layer, but the embodiments of the present disclosure are not limited thereto.

The cathode electrode 153 may be disposed on the organic layer 152. The cathode electrode 153 may be a transparent electrode that transmits light, but the embodiments of the present disclosure are not limited thereto. For example, the cathode electrode 153 may include a transparent conductive material, such as indium tin oxide (ITO) or indium zinc oxide (IZO), or a metal that transmits visible light, but the embodiments of the present disclosure are not limited thereto.

A capping layer 156 may be further disposed on the cathode electrode 153. The capping layer 156 can minimize or reduce damage to the cathode electrode 153 of the light-emitting element EL and the organic layers 152 located below the cathode electrode 153 from an external light source. The capping layer 156 may be formed of an organic or inorganic film.

The capping layer 156 may be disposed using a material, such as LiF or the like, as an inorganic film and may further include an organic film, but the embodiments of the present disclosure are not limited thereto. For example, the capping layer 156 may be formed of the stacking structure of an organic film and an inorganic film, and a thickness of the organic film may differ from a thickness of the inorganic film. In this case, the thickness of the organic film may be greater than the thickness of the inorganic film. As another example, the capping layer 156 may be formed of two or more layers by stacking materials having different refractive indexes. Accordingly, it is possible to increase the light efficiency of the display panel 100.

A bank 154 may be disposed to expose the anode electrode 151. The bank 154 may define the opening (or the light-emitting area EA) of the sub-pixel SP and may be disposed to cover an edge of the anode electrode 151. The organic layer 152 may be disposed in the opening of the sub-pixel SP. That is, the organic layer 152 may be disposed on the anode electrode 151 exposed by the bank 154.

However, the embodiments of the present disclosure are not limited thereto, and the organic layer 152 may be disposed both in the opening (the light-emitting area EA) of the sub-pixel SP and on the bank 154. That is, the organic layer 152 may be disposed in the entirety of the display area DA of the display panel 100.

The bank 154 may be formed of a material containing black pigment, or an organic material, such as a benzocyclobutene resin, a polyimide resin, an acrylic resin, a photosensitive polymer, etc., but the embodiments of the present disclosure are not limited thereto. When the bank 154 is formed of a material containing black pigment or black dye, the bank 154 may be an opaque bank. When the bank 154 is formed of a material containing black pigment or black dye, it is possible to block external light or light reflected from the outside, thereby further increasing the luminance of the display apparatus.

A spacer (not illustrated) may be further disposed on the bank 154. The spacer (not illustrated) may be formed of the same material as the bank 154, but the embodiments of the present disclosure are not limited thereto. The spacer (not illustrated) can prevent or reduce sagging of a mask during a mask process, thereby suppressing or preventing defects, such as imprinting, scratching, or the like, on the display panel 100.

The encapsulation part 170 may be disposed on the bank 154 or the light-emitting part 150. The encapsulation part 170 may include one or more insulating layers. For example, the encapsulation part 170 may include a first inorganic encapsulation layer 171, an organic encapsulation layer 172 formed on the first inorganic encapsulation layer 171, and a second inorganic encapsulation layer 173 formed on the organic encapsulation layer 172. The encapsulation part 170 may include one or more inorganic layers and one or more organic layers. For example, the first inorganic encapsulation layer 171 and the second inorganic encapsulation layer 173 may include an inorganic material, and the organic encapsulation layer 172 may include an organic material, but the embodiments of the present disclosure are not limited thereto.

Even when the first inorganic encapsulation layer 171 and the second inorganic encapsulation layer 173 may be disposed to extend to an end of the non-display area NDA, the organic encapsulation layer 172 may be ended inside the dam part DMP. That is, the organic encapsulation layer 172 may be disposed inside an area surrounded by the dam part DMP without extending beyond the dam part DMP.

The touch part 180 may be disposed on the encapsulation part 170. The touch part 180 may include a touch buffer layer 181, a first touch electrode 182, a first touch insulating layer 183, a black matrix BM, a second touch insulating layer 184, a second touch electrode 185, and a third touch insulating layer 186.

The touch buffer layer 181 may be disposed on the encapsulation part 170. For example, the touch buffer layer 181 may be disposed on the second inorganic encapsulation layer 173. The touch buffer layer 181 may be formed of the same material as the buffer layer 102, but the embodiments of the present disclosure are not limited thereto.

The first touch electrode 182 may be disposed on the touch buffer layer 181.

The first touch insulating layer 183 may be disposed on the first touch electrode 182. The first touch insulating layer 183 may be formed of silicon oxide (SiOx), silicon nitride (SiNx), or multiple layers thereof, but the embodiments of the present disclosure are not limited thereto.

The black matrix BM may be disposed on the first touch insulating layer 183. The black matrix BM may include materials capable of absorbing light. The black matrix BM may include a black pigment or dye, but is not limited thereto. The black matrix BM can prevent or reduce a light leakage defect, etc. that may occur between the sub-pixels SP.

The second touch insulating layer 184 may be disposed on the black matrix BM. The second touch insulating layer 184 may include an organic insulation material. For example, the second touch insulating layer 184 may be formed of photo acryl, benzocyclobutene (BCB), polyimide (PI), or polyamide (PA), but is not limited thereto.

The second touch electrode 185 may be disposed on the second touch insulation layer 184. The second touch electrode 185 may include a la touch electrode 185a extending in the first direction DR1 and a 1b touch electrode 185b extending in the second direction DR2 different from the first direction.

The first touch electrode 182 may be electrically connected to a 2a touch electrode 185a through a contact hole formed in the second touch insulating layer 184. For example, the 2a touch electrode 185a and the first touch electrode 182 may extend in the first direction DR1.

The first touch electrode 182 and the second touch electrode 185 may include a metallic material. For example, the first touch electrode 182 and the second touch electrode 185 may be formed of titanium (Ti), nickel (Ni), aluminum (Al), or an alloy thereof and formed of a triple layer, such as titanium (Ti)/aluminum (Al)/titanium (Ti), but the embodiments of the present disclosure are not limited thereto.

One of the first touch electrode 182 and the second touch electrode 185 may include a function of detecting touch, and the other may include a function of driving touch, but the embodiments of the present disclosure are not limited thereto.

The third touch insulating layer 186 may be disposed on the second touch electrode 185. The third touch insulating layer 186 may be formed of the same material as the first touch insulating layer 183, but is not limited thereto.

The microlens ML (ML1, ML2, and ML3) may be disposed on the third touch insulating layer 186. The microlens ML may include a hemispherical or semi-cylindrical shape, but is not limited thereto. The shape of the microlens ML may vary according to the size, shape, etc. of the light-emitting area EA.

Each microlens ML1, ML2, or ML3 may control a path of light emitted from each pixel PX1, PX2, or PX3. Each microlens ML1, ML2, or ML3 may adjust the path of the light emitted from each pixel PX1, PX2, or PX3 in a different direction.

Accordingly, each pixel PX1, PX2, or PX3 may display a different image and video, and the display apparatus 1 (see FIG. 1) may display three different images and videos according to a viewing angle.

In addition, by arranging the microlens ML (ML1, ML2, and ML3), it is possible to secure a wide viewing angle characteristic, increase luminance, and block leaked light, reflected light, etc., thereby preventing or reducing light leakage.

Each microlens ML (ML1, ML2, or ML3) may include the division line DV (DV1, DV2, or DV3). In a cross section (FIG. 5) cut orthogonally to each of the division lines DV1, DV2, and DV3 in a plan view (see FIG. 4), each of the division lines DV1, DV2, and DV3 may be aligned with the center EC1, EC2, or EC3 of each of the light-emitting areas EA. However, the embodiments of the present disclosure are not limited thereto, and according to the shape of the microlens ML and the shape of the light-emitting area EA, each of the division lines DV1, DV2, and DV3 may not be aligned with the center EC1, EC2, or EC3 of each of the light-emitting areas EA.

The light-blocking pattern BP (BP1 and BP3) may be disposed on the microlens ML. The first light-blocking pattern BP may be disposed on the first microlens ML1, and the third light-blocking pattern BP3 may be disposed on the third microlens ML3. The light-blocking pattern BP may not be disposed on the second microlens ML2, but is not limited thereto.

Each light-blocking pattern BP1 or BP3 may be disposed directly on each microlens ML1 or ML3. Each light-blocking pattern BP1 or BP3 may come into direct contact with each microlens ML1 or ML3, but is not limited thereto.

An area of the surface of the first microlens ML1, which is exposed by the first light-blocking pattern BP1, may come into direct contact with a lens protective layer 190. An area of the surface of the third microlens ML3, which is exposed by the third light-blocking pattern BP3, may come into direct contact with the lens protective layer 190.

When the light-blocking pattern BP is not disposed on the second microlens ML2, the surface of the second microlens ML2 may come into direct contact with the lens protective layer 190 across the entire area.

Here, the surface of each microlens ML1, ML2, or ML3 may refer to an upper surface having a dome shape as an area excluding a lower surface facing the third touch insulating layer 186.

The first light-blocking pattern BP1 and the third light-blocking pattern BP3 may be disposed on two different parts of the microlenses ML1 and ML3 divided by the division lines DV1 and DV3.

For example, the first light-blocking pattern BP1 may be disposed on the first microlens MLI located at one side (or the first side) of the first division line DV1 in the first direction DR1 among the two parts of the first microlens MLI divided by the first division line DV1, and the third light-blocking pattern BP3 may be disposed on the third microlens ML3 located at the other side (or the second side) of the third division line DV3 in the first direction DR1 among the two parts of the third microlens ML3 divided by the third division line DV3.

Accordingly, the first light-blocking pattern BP1 may block some of the light emitted from the first pixel PX1, which travel toward one side in the first direction DR1 in a plan view, and the third light-blocking pattern BP3 may block some of the light emitted from the third pixel PX3, which travel toward the other side in the first direction DR1 in a plan view.

In addition, each light-blocking pattern BP may block both the light emitted from the sub-pixel SP on which each light-blocking pattern BP is disposed and the light emitted from the sub-pixel SP that is disposed around the corresponding sub-pixel SP and incident on the microlens ML of the adjacent sub-pixel SP due to internal reflection of the display panel 100.

Since the light-blocking pattern BP is disposed on the microlens ML, the light-blocking pattern BP can more easily block or control the path of the light emitted from the pixel PX. That is, since the light-blocking pattern BP is disposed on the microlens ML, the light-blocking pattern BP may be disposed at the end of the path along which the light emitted from the pixel PX travels so that the path of the light emitted from the pixel PX may be ultimately blocked and controlled, thereby facilitating the blocking and control of the light.

The lens protective layer 190 may be disposed on the microlens ML (ML1, ML2, and ML3) and the light-blocking pattern BP. The lens protective layer 190 may include an organic insulation material, but is not limited thereto. The lens protective layer 190 may protect the microlens ML by covering the microlens ML.

A refractive index of the lens protective layer 190 may be smaller than a refractive index of the microlens ML. Accordingly, due to a difference in refractive index between the microlens ML and the lens protective layer 190, light that has passed through the microlens ML can be prevented or reduced from being reflected toward the substrate 101.

Hereinafter, a cross-sectional structure of the non-display area NDA of the display apparatus 1 will be described. The same content as that described in the cross-sectional structure of the display area DA will be briefly described or omitted.

Subsequently, referring further to FIGS. 1, 3, and 7 to 9, the display panel 100 may further include the gate control transistor G120, the low-potential voltage line VSSL, the dam part DMP, the plurality of pads VSSP, VDDP, and DP disposed in the pad area PA, the data line DL (DL1 and DL2), and a crack prevention pattern CSP, which are disposed in the non-display area NDA.

The gate control transistor G120 may have substantially the same configuration as the thin film transistor 120 of the sub-pixel SP and may be formed together by the same process as the thin film transistor 120 of the sub-pixel SP, but is not limited thereto.

The gate control transistor G120 may include a control source electrode G121, a control gate electrode G122, a control semiconductor layer G123, and a control drain electrode G124.

A light-blocking layer (not illustrated) may be further disposed under the gate control transistor G120. One of the control source electrode G121 and the control drain electrode G124 may be electrically connected in contact with the light-blocking layer (not illustrated), but is not limited thereto.

The low-potential voltage line VSSL may be disposed on the fourth insulating layer 106. The low-potential voltage line VSSL may be formed of the same metal layer as the source electrode 121 and the drain electrode 124 of the thin film transistor 120, but is not limited thereto.

The display panel 100 may further include a low-potential connection electrode CE. The low-potential connection electrode CE may connect the low-potential voltage line VSSL to the cathode electrode 153.

The low-potential connection electrode CE may be disposed on the second protective layer 112. The bank 154 may be disposed on the low-potential connection electrode CE. The low-potential connection electrode CE may be disposed on the same layer as the anode electrode 151 and may include the same material as the anode electrode 151, and the low-potential connection electrode CE and the anode electrode 151 may be formed together using one mask by the same process, but the embodiments of the present disclosure are not limited thereto.

The display panel 100 may further include an exposed part OP. The exposed part OP may expose at least a part of the low-potential voltage line VSSL by recessing the first protective layer 111 and the second protective layer 112.

The exposed part OP may be defined by the first protective layer 111 and the second protective layer 112. The exposed part OP may be defined by a side surface of the first protective layer 111, a side surface of the second protective layer 112, and a side surface of a second dam DM2.

The low-potential connection electrode CE may be electrically connected in contact with the low-potential voltage line VSSL exposed in the exposed part OP. At least a part of the low-potential connection electrode CE may be disposed on the second protective layer 112 and may extend from the second protective layer 112 toward the low-potential voltage line VSSL.

The low-potential connection electrode CE may be further disposed on the side surface of the first protective layer 111 that defines the exposed part OP and the side surface of the second protective layer 112 and may be further disposed on the fourth insulating layer 106 and the low-potential voltage line VSSL that are exposed by the exposed part OP. Accordingly, the low-potential connection electrode CE may come into contact with the low-potential voltage line VSSL.

The low-potential connection electrode CE may be electrically connected to the cathode electrode 153. The low-potential connection electrode CE and the cathode electrode 153 may be electrically connected in contact with each other through a low-potential contact hole C_CNT in an overlapping area. The low-potential contact hole C_CNT may be defined by passing through the bank 154 in the area in which the low-potential connection electrode CE and the cathode electrode 153 overlap each other and may expose the low-potential connection electrode CE.

The dam part DMP may include a first dam DM1 and a second dam DM2. The first dam DM1 and the second dam DM2 may overlap a first low-potential voltage line VSSL1 or a second low-potential voltage line VSSL2.

In the second non-display area NDA2, the first dam DM1 and the second dam DM2 may overlap the first low-potential voltage line VSSL1. In the first non-display area NDA1, the first dam DM1 and the second dam DM2 may overlap the second low-potential voltage line VSSL2.

The first dam DM1 may be disposed outside the second dam DM2, but is not limited thereto.

The first dam DM1 may be formed in a multilayered structure. Each layer of the first dam DM1 may include the same material as the second protective layer 112 and the bank 154, and each layer of the first dam DM1, the second protective layer 112, and the bank 154 may be formed together using one mask by the same process, but the embodiments of the present disclosure are not limited thereto.

The second dam DM2 may be formed in a multilayered structure. Each layer of the second dam DM2 may include the same material as the bank 154 and the spacer (not illustrated), and each layer of the second dam DM2, the bank 154, and the spacer (not illustrated) may be formed together using one mask by the same process, but the embodiments of the present disclosure are not limited thereto.

The crack prevention pattern CSP may be disposed at an outermost edge of the non-display area NDA. The crack prevention pattern CSP may be defined by recessing at least one of the inorganic films disposed on the substrate 101.

For example, the crack protection pattern CSP may be defined by recessing the first insulating layer 103, the second insulating layer 104, the third insulating layer 105, and the fourth insulating layer 106, but is not limited thereto.

A crack dummy pattern DUP may be further disposed on the crack protection pattern CSP. The crack dummy pattern DUP may fill the recessed crack protection pattern CSP. The crack dummy pattern DUP may be formed of multiple layers. For example, the crack dummy pattern DUP may be formed of three layers. Layers of the crack dummy pattern DUP may include the same material as the first protective layer 111, the second protective layer 112, and the bank 154.

The high-potential voltage line VDDL may be disposed on the buffer layer 102 and covered by the first insulating layer 103. The high-potential voltage line VDDL may include the same material as the light-blocking layer 126, and the high-potential voltage line VDDL and the light-blocking layer 126 may be formed together using one mask by the same process, but the embodiments of the present disclosure are not limited thereto.

Although not illustrated, the high-potential voltage pad VDDP may be disposed on the same layer as the source electrode 121 and the drain electrode 124, may include the same material as the source electrode 121 and the drain electrode 124, and may be formed together using one mask by the same process as the source electrode 121 and the drain electrode 124, but is not limited thereto.

In this case, the high-potential voltage pad VDDP may be electrically connected in contact with the high-potential voltage line VDDL through the high-potential contact hole S_CNT that exposes the high-potential voltage line VDDL.

However, the embodiments of the present disclosure are not limited thereto, and the high-potential voltage line VDDL may be disposed on the same layer as the source electrode 121 and the drain electrode 124 and may include the same material as the source electrode 121 and the drain electrode 124, and the high-potential voltage line VDDL, the source electrode 121, and the drain electrode 124 may be formed together using one mask by the same process.

The first data pad DPI and the second data pad DP2 may be disposed on the fourth insulating layer 106. The first data pad DP1 and the second data pad DP2 may be disposed on the same layer as the source electrode 121 and the drain electrode 124, may include the same material as the source electrode 121 and the drain electrode 124, and may be formed together using one mask by the same process as the source electrode 121 and the drain electrode 124, but are not limited thereto.

The first data line DL1 may be disposed on the second insulating layer 104 and covered by the third insulating layer 105. The first data line DL1 may include the same material as the gate electrode 122 and may be formed together using one mask by the same process as the gate electrode 122, but is not limited thereto.

The second data line DL2 may be disposed on the third insulating layer 105 and covered by the fourth insulating layer 106. The second data line DL2 may include the same material as the second storage electrode 142 and may be formed together using one mask by the same process as the second storage electrode 142, but is not limited thereto.

The first data line DL1 may be electrically connected in contact with the first data pad DP1 through the first data contact hole CNT1. The second data line DL2 may be electrically connected in contact with the second data pad DP2 through the second data contact hole CNT2.

The crack prevention pattern CSP may be disposed outside the pad area PA. The crack prevention pattern CSP may be disposed between the ends of the pad area PA and the non-display area NDA2.

However, the plurality of pads VSSP, VDDP, and DP may not be covered by a plurality of inorganic films. The plurality of inorganic films disposed on the fourth insulating layer 106 may expose the plurality of pads VSSP, VDDP, and DP. The plurality of inorganic films disposed on the fourth insulating layer 106 may not be disposed in the pad area PA.

Accordingly, the flexible film COF may be configured so that at least a part thereof is disposed to overlap the pad area PA and attached to the display panel 100, and the flexible film COF may be electrically connected in contact with the plurality of pads VSSP, VDDP, and DP of the pad area PA.

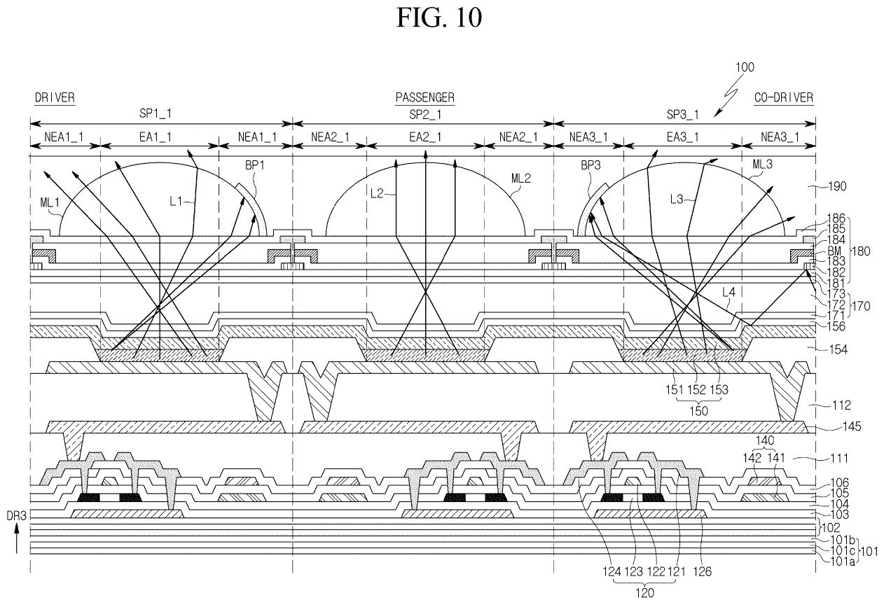

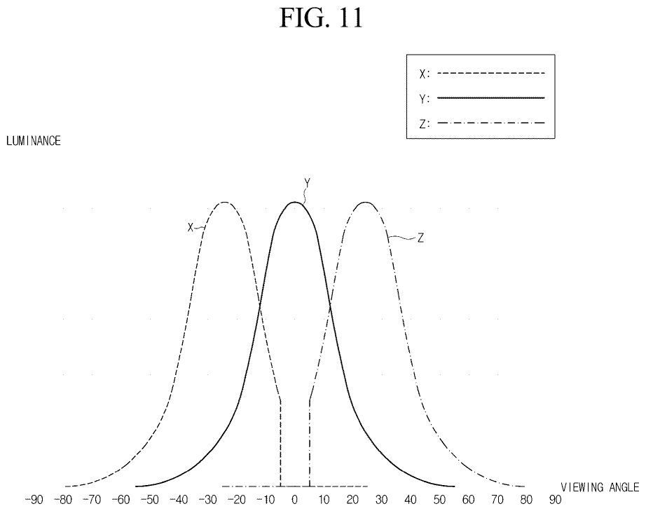

FIG. 10 is a schematic view illustrating a path of light emitted from the display panel according to an example embodiment of the present disclosure. FIG. 11 is a graph illustrating luminance according to a viewing angle of the display apparatus according to an example embodiment of the present disclosure.

As shown in FIGS. 4, 10, and 11, the first light-blocking pattern BP1 may be disposed on the first microlens ML1, the light-blocking pattern BP may not be disposed on the second microlens ML2, and the third light-blocking pattern BP3 may be disposed on the third microlens ML3.

The first light-blocking pattern BP1 and the third light-blocking pattern BP3 may be disposed on two different parts of the microlenses ML1 and ML3 divided by the division lines DV1 and DV3.

The first light-blocking pattern BP1 may be disposed on the first microlens ML1 located at one side (or the first side) of the first division line DV1 in the first direction DR1 among the two parts of the first microlens ML1 divided by the first division line DV1, and the third light-blocking pattern BP3 may be disposed on the third microlens ML3 located at the other side (or the second side) of the third division line DV3 in the first direction DR1 among the two parts of the third microlens ML3 divided by the third division line DV3.

The first pixel PX1 may emit first light L1 to display a first screen to the driver DRIVER sitting on the driver's seat. The first light-blocking pattern BP1 may block some of the first light L1 emitted from the first pixel PX1, which travel toward one side in the first direction DR1 in a plan view. The first light-blocking pattern BP1 may block some of the first light L1, which travels toward the passenger CO-DRIVER sitting on the front passenger's seat and/or the passenger PASSENGER sitting on the rear seat.

The third pixel PX3 may emit third light L3 to display a third screen to the passenger CO-DRIVER sitting on the front passenger's seat. The third light-blocking pattern BP3 may block some of the third light L3 emitted from the third pixel PX3, which travel toward the other side in the first direction DR1 in a plan view. The third light-blocking pattern BP3 may block some of the third light L3, which travel toward the driver DRIVER sitting on the driver's seat and/or the passenger PASSENGER sitting on the rear seat.

In addition, each light-blocking pattern BP may block both the light emitted from the sub-pixel SP on which each light-blocking pattern BP is disposed and the light emitted from the sub-pixel SP that is disposed around the corresponding sub-pixel SP and incident on the microlens ML of the adjacent sub-pixel SP due to internal reflection of the display panel 100.

For example, fourth light L4 emitted from the sub-pixel SP not illustrated in FIG. 11 may be reflected inside the display panel 100 and emitted from the 3_1 sub-pixel SP3_1. When the path of the fourth light L4 emitted from the 3_1 sub-pixel SP3_1 faces the driver DRIVER, the fourth light L4 may be blocked by the third microlens ML3 disposed on the 3_1 sub-pixel SP3_1.

The second pixel PX2 may emit the second light L2 to display a second screen to the passenger PASSENGER sitting on the rear seat or display the same screen to both the driver DRIVER and the passengers CO-DRIVER and PASSENGER. The second microlens ML2 may condense the second light L2, thereby minimizing or reducing a reduction in luminance of the light emitted from the second pixel PX2.

In addition, since the light-blocking pattern BP is not disposed on the second microlens ML2, the second light L2 is not blocked, and thus it is possible to more easily minimize or reduce the reduction in luminance of the light emitted from the second pixel PX2.

The first pixel PX1, the second pixel PX2, and the third pixel PX3 may be individually controlled to display different screens. The screen displayed by each of the first pixel PX1, the second pixel PX2, and the third pixel PX3 may be recognized according to) a viewing angle. That is, the user may recognize the screen displayed by the first pixel PX1, the screen displayed by the second pixel PX2, or the screen displayed by the third pixel PX3 according to a viewing angle.

When the first pixel PX1, the second pixel PX2, and the third pixel PX3 display different screens according to a viewing angle, it is possible to suppress or prevent crosstalk between the screens by arranging the light-blocking patterns BP1 and BP3.

In FIG. 11, a horizontal axis represents a viewing angle, and a vertical axis represents luminance. In FIG. 11, graph X represents luminance by the first pixel PX1, graph Y represents luminance by the second pixel PX2, and graph Z represents luminance by the third pixel PX3.

Graph X represents luminance of the screen recognized by the driver DRIVER sitting on the driver's seat, graph Y represents the luminance of the screen recognized by the passenger PASSENGER sitting on the rear seat or all of the driver DRIVER and the passengers CO-DRIVER and PASSENGER, and graph Z represents the luminance of the screen recognized by the passenger CO-DRIVER sitting on the front passenger's seat.

Graphs X, Y, and Z may have different peaks according to a viewing angle. Graph X may have a bell curve having a peak at a viewing angle between −20 and −30, graph Y may have a bell curve having a peak at a viewing angle near 0, and graph Z may have a bell curve having a peak at a viewing angle between 20 and 30.

As the light-blocking patterns BP1 and BP3 are disposed on the microlenses ML1 and ML3 to block some of the light emitted from the first pixel PX1 and the third pixel PX3, graph X and graph Z may include a point at which the luminance abruptly decreases in some area overlapping graph Y and/or an area in which graph X and graph Z may overlap each other.

In Graph X, the luminance abruptly decreases and converges to 0 at one point between −10 and 0, and the luminance continuously converges to 0 at angles after the corresponding point. In Graph Z, the luminance abruptly decreases and converges to 0 at one point between 0 and 10, and the luminance continuously converges to 0 at angles after the corresponding point.

Since the light-blocking pattern BP is not disposed on the second microlens ML2, graph Y may have a bell curve in the entire area.

Since the light-blocking pattern BP is disposed, the first light L1 emitted by the first pixel PX1 may be blocked at some viewing angles, and the third light L3 emitted by the third pixel PX3 may be blocked at other viewing angles.

Accordingly, the area in which graphs X, Y, and Z overlap each other may decrease, and it is possible to suppress or prevent crosstalk on each screen provided to the driver DRIVER and the passengers CO-DRIVER and PASSENGER, thereby improving the quality of each screen.

Hereinafter, other example embodiments of the present disclosure will be described. For contents that are substantially the same as those described with reference to FIGS. 1 to 11 among components included in other example embodiments, the same reference numerals are given, and overlapping contents may be omitted or briefly described.

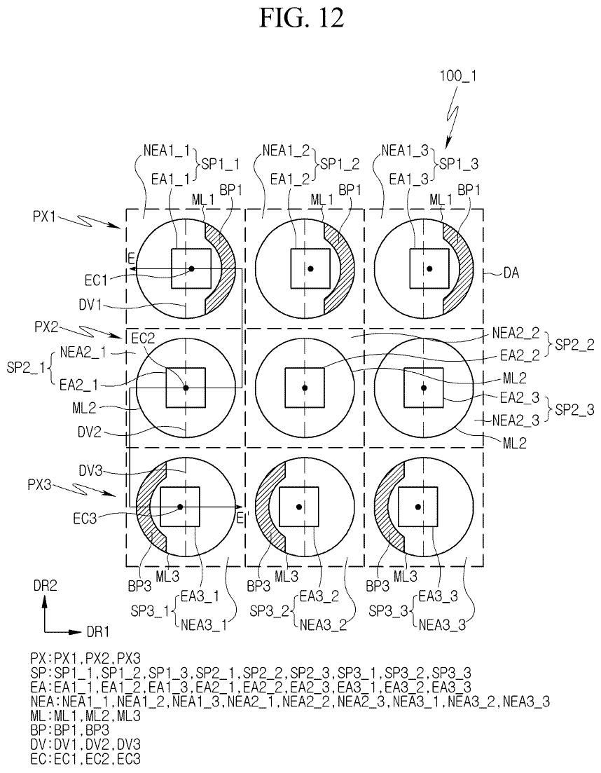

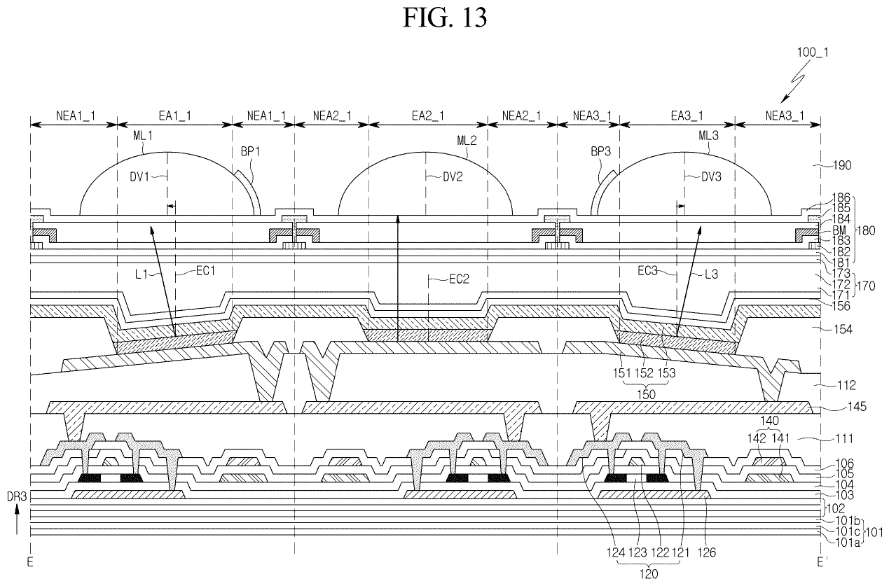

FIG. 12 is an enlarged view illustrating a pixel arrangement of a display panel according to still another example embodiment. FIG. 13 is a cross-sectional view along line E-E′ in FIG. 12.

As shown in FIGS. 12 and 13, in a display panel 100_1 according to the present example embodiment, the first division line DV1 of the first microlens ML1 and the first center EC1 of the light-emitting areas EA1_1, EA1_2, and EA1_3 of the first pixel PX1 may be misaligned, and the third division line DV3 of the third microlens ML3 and the third center EC3 of the light-emitting areas EA3_1, EA3_2, and EA3_3 of the third pixel PX3 may be misaligned. In addition, at least a part of the light-emitting part 150 may be disposed to be inclined in the thickness direction (the third direction DR3).

Specifically, in the area in which the light-emitting part 150 is disposed, a part of an upper surface of the second protective layer 112 may be formed to be inclined. The light-emitting part 150 may be disposed on the second protective layer 112 of which at least a part is inclined. Accordingly, at least a part of each of the anode electrode 151 and the organic layer 152 may be tilted. The at least a part of each of the anode electrode 151 and the organic layer 152 may be tilted (inclined) toward the microlens ML.

Each of the anode electrode 151 and the organic layer 152 may be disposed on the second protective layer 112 of which at least a part is inclined. The organic layer 152 may be disposed on the second protective layer 112 of which the entire area is inclined, but is not limited thereto.

The anode electrode 151 and the organic layer 152 that are disposed on the inclined second protective layer 112 may be disposed to be inclined (tilted) corresponding to the inclined second protective layer 112. Accordingly, a part of the cathode electrode 153 disposed on the organic layer 152 may be disposed to be inclined.

The anode electrode 151 and the organic layer 152 may be disposed to be inclined in the thickness direction (the third direction DR3) of the display panel 100 in the 1_1 light-emitting area EA1_1, the 3_1 light-emitting area EA3_1, and peripheries thereof. An upper surface of the anode electrode 151 and an upper surface of the organic layer 152 may be inclined in the thickness direction (the third direction DR3) of the display panel 100. A direction in which the upper surface of the anode electrode 151 and the upper surface of the organic layer 152 face may be inclined in the thickness direction (the third direction DR3) of the display panel 100.

The upper surface of the anode electrode 151 and the upper surface of the organic layer 152 may be inclined with respect to an upper surface of the first protective layer 111.

The anode electrode 151 and the organic layer 152 of the first pixel PX1 may be inclined in a different direction from the anode electrode 151 and the organic layer 152 of the third pixel PX3. For example, in the 1-1 light-emitting area EA1_1, the 3-1 light-emitting area EA3_1, and peripheries thereof, directions in the anode electrode 151 and the organic layer 152 are tilted may be opposite.

The upper surface of the anode electrode 151 and the upper surface of the organic layer 152 of the first pixel PX1 may be tilted toward the first microlens ML1, and the upper surface of the anode electrode 151 and the upper surface of the organic layer 152 of the third pixel PX3 may be tilted toward the third microlens ML3.

Accordingly, light emitted from each sub-pixel SP may be tilted in the thickness direction (the third direction DR3) of the display panel 100.

The first center EC1 of the 1_1 light-emitting area EA1_1 of the 1_1 sub-pixel SP1_1 and the first division line DV1 of the first microlens ML1 disposed on the 1_1 sub-pixel SP1_1 may be misaligned. In a plan view, the division line DV1 of the first microlens ML1 may be misaligned from the first center EC1 of the 1_1 light-emitting area EA1_1 to the other side (the left in a plan view) in the first direction DR1.

The description of the misalignment of the 1_1 sub-pixel SP1_1 may also be applied to the remaining sub-pixels SP1_2 and SP1_3 of the first pixel PX1 in substantially the same manner. However, in each of the sub-pixels SP1_1, SP1_2, and SP1_3 of the first pixel PX1, the degree of misalignment between the microlens ML and the light-emitting area EA may be different.

However, the embodiments of the present disclosure are not limited thereto, and a direction in which the first division line DV1 of the first microlens ML1 and the first center EC1 of the 1_1 light-emitting area EA1_1 are misaligned may vary according to a design.

The third center EC3 of the 3_1 light-emitting area EA3_1 of the 3_1 sub-pixel SP3_1 and the third division line LC3 of the third microlens ML3 disposed on the 3_1 sub-pixel SP3_1 may be misaligned. In a plan view, the third division line LC3 of the third microlens ML3 may be misaligned from the third center EC3 of the 3_1 light-emitting area EA3_1 to one side (the right in a plan view) in the first direction DR1.

The description of the misalignment of the 3_1 sub-pixel SP3_1 may also be applied to the remaining sub-pixels SP3_2 and SP3_3 of the third pixel PX3 in substantially the same manner. However, in each of the sub-pixels SP3_1, SP3_2, and SP3_3 of the third pixel PX3, the degree of misalignment between the microlens ML and the light-emitting area EA may be different.

However, the embodiments of the present disclosure are not limited thereto, and a direction in which the third division line LC3 of the third microlens ML3 and the third center EC3 of the 3_1 light-emitting area EA3_1 are misaligned may vary according to a design.

The opening (or the light-emitting area EA) of the sub-pixel SP and the light-emitting part 150 disposed around the opening may be disposed to be tilted with respect to the thickness direction (the third direction DR3), and the light L1 and L3 emitted from the light-emitting part 150 may travel in a direction that is tilted with respect to the thickness direction (the third direction DR3).

Since the microlens ML and the light-emitting area EA are misaligned, even when the light L1 and L3 emitted from the light-emitting part 150 travels while being tilted with respect to the thickness direction (the third direction DR3), each light L1 or L3 may travel toward the microlens ML.

The sub-pixels SP1_1, SP1_2, and SP1_3 disposed in the first pixel PX1 may emit the light L1 to the left (the other side in the first direction DR1) in a plan view. The sub-pixels SP3_1, SP3_2, and SP3_3 disposed in the third pixel PX3 may emit the light L3 to the right (one side in the first direction DR1) in a plan view.

That is, the light L1 emitted from the sub-pixels SP1_1, SP1_2, and SP1_3 of the first pixel PX1 may travel while being tilted to the other side in the first direction DR1 with respect to the thickness direction (the third direction DR3). The light L3 emitted from the sub-pixels SP3_1, SP3_2, and SP3_3 of the third pixel PX3 may travel while being tilted to one side in the first direction DR1 with respect to the thickness direction (the third direction DR3).

The direction and degree of misalignment of the microlens ML and the light-emitting area EA may vary according to the traveling direction of the light emitted from the sub-pixels SP of each pixel PX1 or PX2.

Since the sub-pixels SP1_1, SP1_2, and SP1_3 disposed in the first pixel PX1 and the sub-pixels SP3_1, SP3_2, and SP3_3 disposed in the third pixel PX3 may emit light in different directions, the screen displayed to the driver DRIVER sitting on the driver's seat and the screen displayed to the front passenger PASSENGER sitting on the front passenger's seat may be distinctly controlled separately, and different screens may be displayed to the driver DRIVER and the front passenger CO-DRIVER.

In addition, the light-emitting part 150 of each sub-pixel SP2_1, SP2_2, or SP2_3 of the second pixel PX2 may not be tilted. The light L2 emitted from the second pixel PX2 may travel in the thickness direction (the third direction DR3). The light L2 emitted from the second pixel PX2 may be emitted in a different direction from the light L1 emitted from the first pixel PX1 and the light L3 emitted from the third pixel PX3.

Accordingly, not only the screen displayed to the driver DRIVER sitting on the driver's seat and the passenger CO-DRIVER sitting on the front passenger's seat, but also the passenger PASSENGER sitting on the rear seat may be controlled separately, and different screens may be displayed to the driver DRIVER and the passengers CO-DRIVER and PASSENGER.

The light L1 emitted from the first pixel PX1 may be emitted toward the first microlens ML1 on which the first light-blocking pattern BP1 is not disposed. The light L3 emitted from the third pixel PX3 may be emitted toward the third microlens ML3 on which the third light-blocking pattern BP3 is not disposed.

The light-blocking patterns BP1 and BP3 may block and absorb the light emitted from each pixel PX1, PX2, or PX3 and traveling in an undesired direction. Even in this case, since the light-blocking pattern BP is disposed on the microlens ML, it is possible to suppress or prevent crosstalk that may occur between images and videos displayed on each pixel PX1, PX2, or PX3.

In addition, since the light-emitting part 150 of some pixels PX1 and PX3 is tilted, the path of the light emitted from each pixel PX1, PX2, or PX3 can be more easily controlled, and different images and videos can be more easily displayed according to a viewing angle.

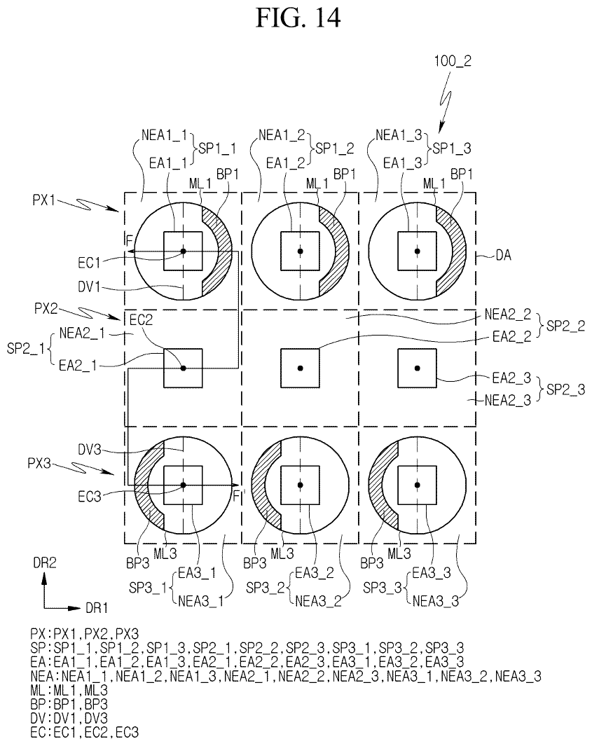

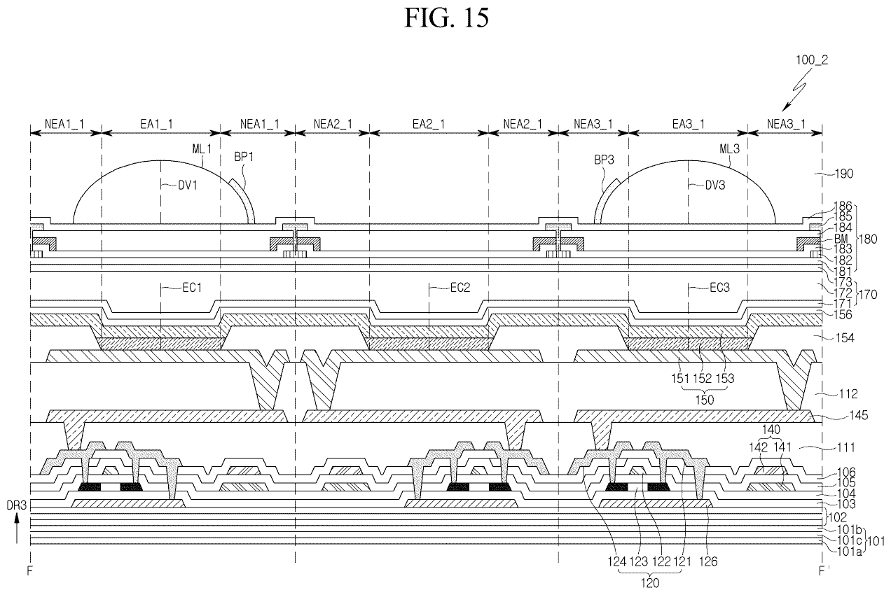

FIG. 14 is an enlarged view illustrating a pixel arrangement of a display panel according to still another example embodiment of the present disclosure. FIG. 15 is a cross-sectional view along line F-F′ in FIG. 14.

As shown in FIGS. 14 and 15, a display panel 100_2 according to the present example embodiment may not have the microlens ML disposed on the second pixel PX2.

Specifically, on the first pixel PX1, the first microlens ML1 and the first light-blocking pattern BP1 may be disposed in each sub-pixel SP, and on the third pixel PX3, the third microlens ML3 and the third light-blocking pattern BP3 may be disposed in each sub-pixel SP, but the microlens ML may not be disposed on the second pixel PX2.

In the area in which the second pixel PX2 is disposed, the third touch insulation layer 186 and the lens protective layer 190 may come into direct contact with each other across the entire area. That is, the third touch insulation layer 186 and the lens protective layer 190 may come into direct contact with each other across the light-emitting areas EA2_1, EA2_2, and EA2_3 and the non-light-emitting areas NEA2_1, NEA2_2, and NEA2_3 of the second pixel PX2.

The light-blocking patterns BP1 and BP3 may block and absorb the light emitted from each pixel PX1, PX2, or PX3 and traveling in an undesired direction. Even in this case, since the light-blocking pattern BP is disposed on the microlens ML, it is possible to suppress or prevent crosstalk that may occur between images and videos displayed on each pixel PX1, PX2, or PX3.

In addition, since the microlens ML is not disposed on the second pixel PX2, it is possible to reduce a material required for the process of forming the microlens ML, thereby reducing process cost and further simplifying the process.

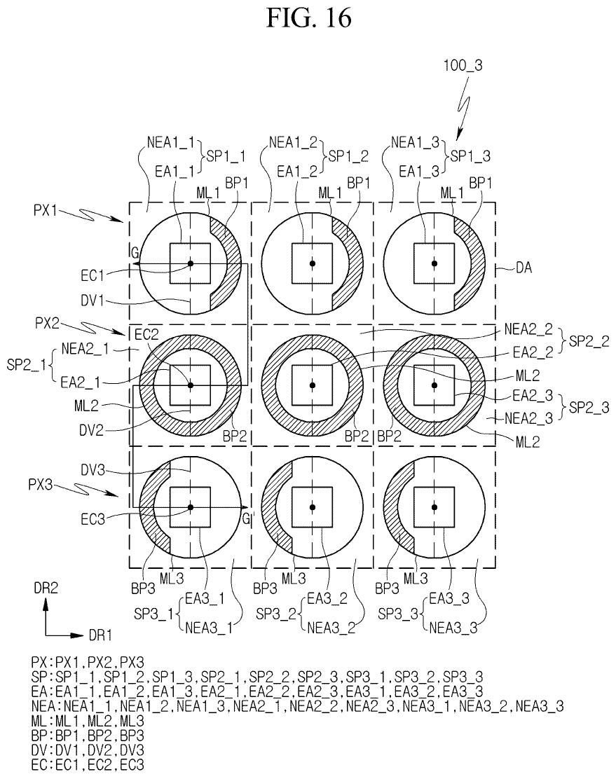

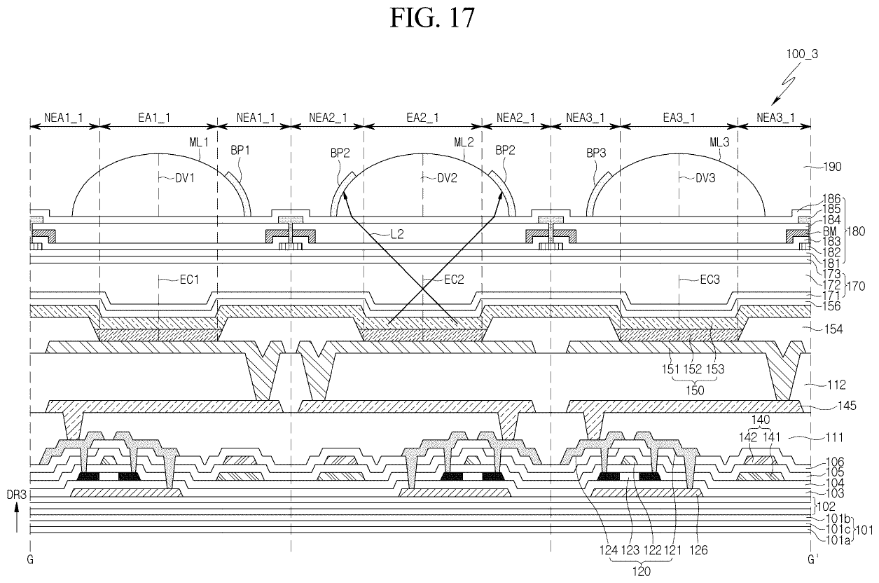

FIG. 16 is an enlarged view illustrating a pixel arrangement of a display panel according to yet another example embodiment of the present disclosure. FIG. 17 is a cross-sectional view along line G-G′ in FIG. 16.

As shown in FIGS. 16 and 17, a display panel 100_3 according to the present example embodiment may further include a second light-blocking pattern BP2 disposed on the second microlens ML2.

Specifically, the display panel 100_3 may include the second light-blocking pattern BP2, and the second light-blocking pattern BP2 may be disposed on the second microlens ML2.

The second light-blocking pattern BP2 may be disposed on the second pixel PX2 and disposed in each sub-pixel PX2_1, PX2_2, or PX2_3 of the second pixel PX2.

The second light-blocking pattern BP2 may be disposed along an edge of the second microlens ML2. Accordingly, the second light-blocking pattern BP2 may block and absorb some of the light L2 emitted from the second pixel PX2, which travel in an undesired direction.

Since not only the first light-blocking pattern BP1 and the third light-blocking pattern BP3 but also the second light-blocking pattern BP2 are disposed, the light emitted from each pixel PX1, PX2, or PX3 and traveling in an undesirable direction can be more smoothly blocked and absorbed. Since the light-blocking pattern BP is disposed on the microlens ML, it is possible to suppress or prevent crosstalk that may occur between images and videos displayed on each pixel PX1, PX2, or PX3.

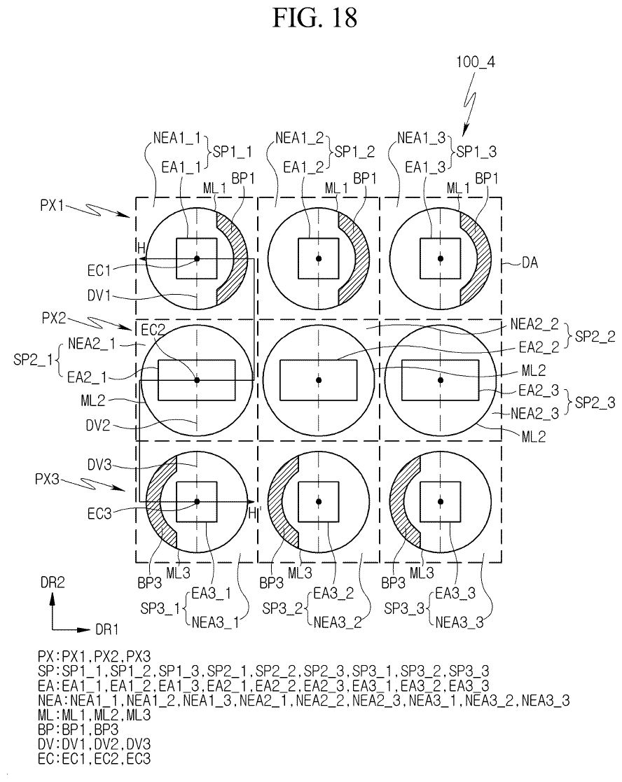

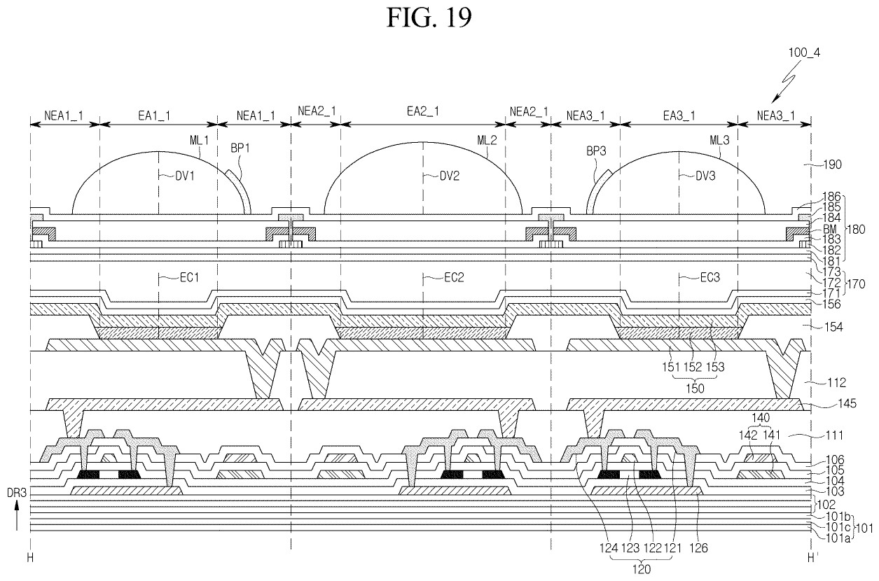

FIG. 18 is an enlarged view illustrating a pixel arrangement of a display panel according to yet another example embodiment of the present disclosure. FIG. 19 is a cross-sectional view along line H-H′ in FIG. 18.

As shown in FIGS. 18 and 19, sizes of the light-emitting areas EA2_1, EA2_2, and EA2_3 of the second pixel PX2 may be greater than sizes of the light-emitting areas EA1_1, EA1_2, and EA1_3 of the first pixel PX1 and sizes of the light-emitting areas EA3_1, EA3_2, and EA3_3 of the third pixel PX3.

An area of the anode electrode 151 exposed by the bank 154 in the second pixel PX2 may be greater than an area of the anode electrode 151 exposed by the bank 154 in the first pixel PX1 and an area of the anode electrode 151 exposed by the bank 154 in the third pixel PX3.

A size (or an area) of the second microlens ML2 disposed on the second pixel PX2 may be greater than a size (or an area) of the first microlens ML1 disposed on the first pixel PX1 and a size (or an area) of the third microlens ML3 disposed on the third pixel PX3, but is not limited thereto.

The first light-blocking pattern BP1 may be disposed on the first pixel PX1 and the third light-blocking pattern BP3 may be disposed on the third pixel PX3, but the light-blocking pattern BP may not be disposed on the second pixel PX2.

The light-blocking patterns BP1 or BP3 may block and absorb the light emitted from each pixel PX1 or PX3 and traveling in an undesired direction. Even in this case, since the light-blocking pattern BP is disposed on the microlens ML, it is possible to suppress or prevent crosstalk that may occur between images and videos displayed on each pixel PX1, PX2, or PX3.

In addition, the luminance of a display panel 100_4 can be improved by the sizes of the light-emitting areas EA2_1, EA2_2, and EA2_3 of the second pixel PX2. Furthermore, it is possible to improve the luminance of the image and video displayed by the second pixel PX2, thereby improving image quality.

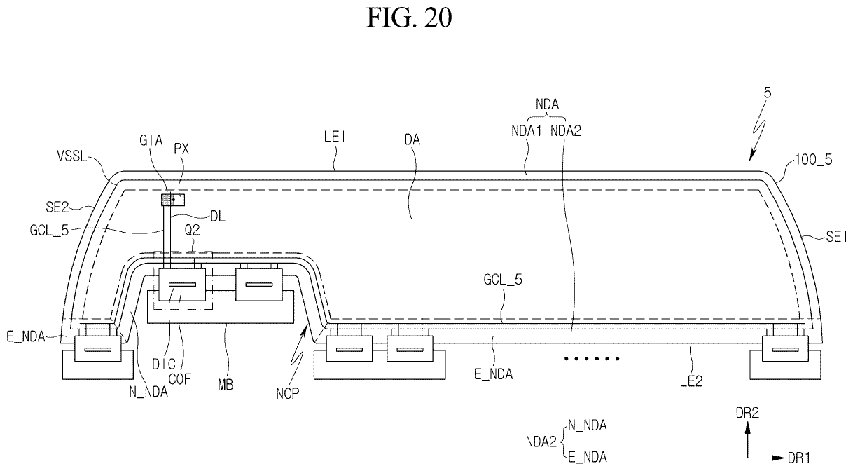

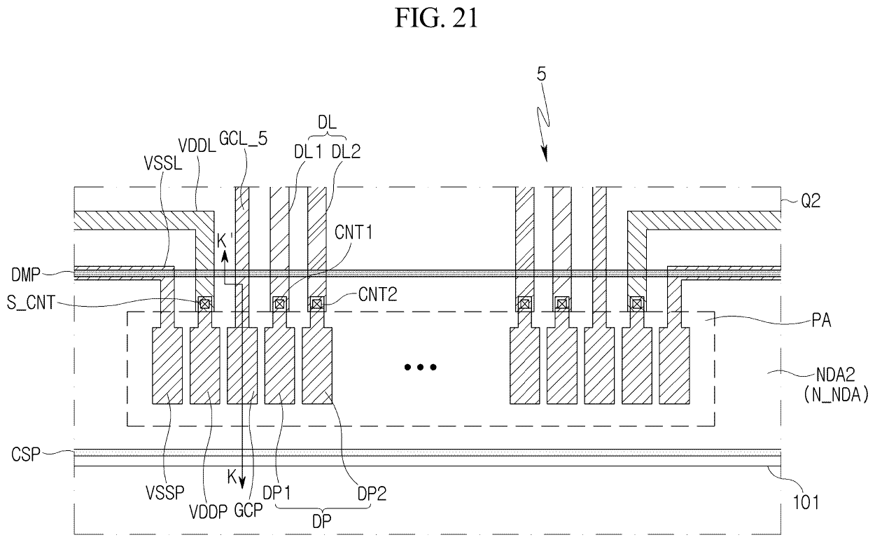

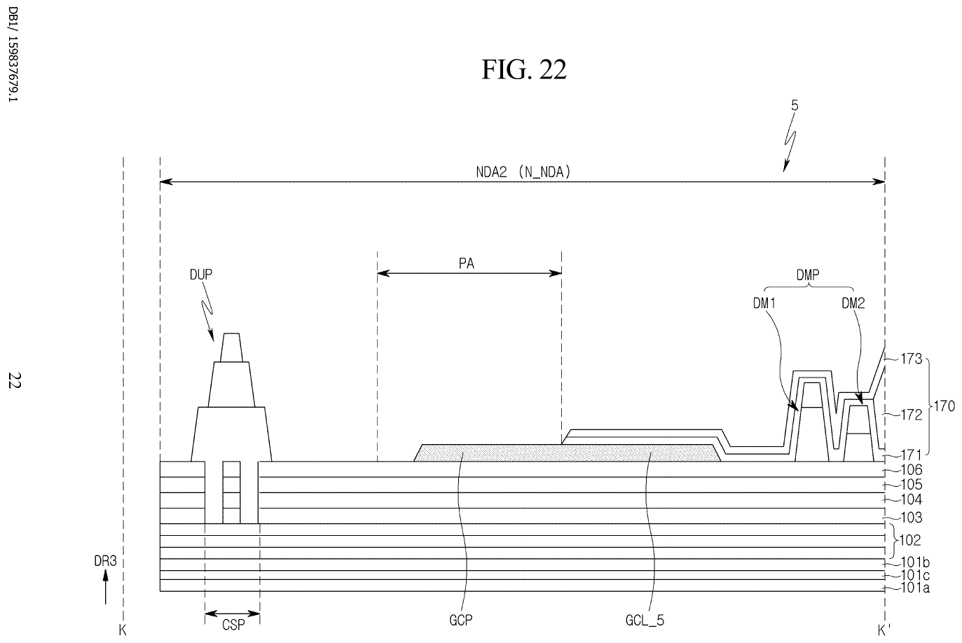

FIG. 20 is a plan view of a display apparatus according to another example embodiment of the present disclosure. FIG. 21 is an enlarged view of area Q2 in FIG. 20. FIG. 22 is a cross-sectional view along line K-K′ in FIG. 21.

FIG. 22 is a view of area Q2 of a display apparatus 2 according to yet another example embodiment, from which the flexible film COF, the main board MB, and the drive IC DIC are omitted.

As shown in FIGS. 20 to 22, in a display apparatus 5 according to the present example embodiment, the gate driving unit GIP (see FIG. 1) may not separately be disposed in the non-display area NDA, and a pixel gate driving unit GIA may be disposed in the display area DA.

The pixel gate driving unit GIA may be provided as a plurality of pixel gate drivers, and each pixel gate driving unit GIA may be connected to each of the plurality of pixels PX. The pixel gate driving unit GIA may be disposed around the pixel PX. The pixel gate driving unit GIA may be disposed between adjacent pixels PX.

For example, the pixel gate driving unit GIA may be disposed between adjacent pixels PX in the first direction DR1. The pixel PX and the pixel gate driving unit GIA may be alternately repeatedly disposed in the first direction DR1. The pixel PX may be continuously repeatedly disposed in the second direction DR2. The pixel gate driving unit GIA may be continuously repeatedly disposed in the second direction DR2.

The pixel gate driving unit GIA may perform substantially the same role as the gate driving unit GIP (see FIG. 1). The pixel gate driving unit GIA may include at least one transistor.

The pixel gate driving unit GIA may be electrically connected to an adjacent pixel PX.

The pixel gate driving unit GIA may receive a gate control signal from the drive IC DIC through a gate control line GCL_5. The pixel gate driving unit GIA may generate a scan signal and a light-emitting signal (or a light-emitting control signal) based on the gate control signal. Accordingly, the driving of the adjacent pixel PX may be controlled.

Since the pixel gate driving unit GIA is disposed in the display area DA, it is possible to minimize or reduce the non-display area NDA or the bezel area, thereby providing improved aesthetic feeling to a user.

The display apparatus 5 may further include the gate control line GCL_5 and a gate control pad GCP.

The gate control line GCL_5 may be disposed in the non-display area NDA and the display area DA. The gate control line GCL_5 may be disposed in the second non-display area NDA2, but is not limited thereto. The gate control line GCL_5 may be disposed in an extension direction of the second non-display area NDA2.

The gate control line GCL_5 may be partially disposed in the second non-display area NDA2 and may extend from the second non-display area NDA2 to the pixel gate driving unit GIA of the display area DA. The gate control line GCL_5 may be electrically connected to the plurality of pixel gate driving units GIAs disposed in the display area DA.

The gate control pad GCP may be disposed in the pad area PA. In the pad area PA, the gate control pad GCP is illustrated as being disposed between the high-potential voltage pad VDDP and the data pad DP, but is not limited thereto, and the arrangement location of the gate control pad GCP may vary according to a design.

The gate control pad GCP may include the same material as the gate control line GCL_5, but is not limited thereto. The gate control pad GCP and the gate control line GCL_5 may be formed integrally, but are not limited thereto.

The gate control pad GCP and the gate control line GCL_5 may be disposed on the fourth insulating layer 106. The gate control pad GCP and the gate control line GCL_5 may be disposed on the same layer as the source electrode 121 (see FIG. 5) and the drain electrode 124 (see FIG. 5) and may include the same material as the source electrode 121 and the drain electrode 124, and the gate control pad GCP, the gate control line GCL, the source electrode 121, and the drain electrode 124 may be formed together using one mask by the same process, but the embodiments of the present disclosure are not limited thereto.

The plurality of pads VSSP, VDDP, DP, and GCP may not be covered by the plurality of inorganic films. The plurality of inorganic films disposed on the fourth insulating layer 106 may expose the plurality of pads VSSP, VDDP, DP, and GCP. The plurality of inorganic films disposed on the fourth insulating layer 106 may not be disposed in the pad area PA.

For example, the first inorganic encapsulation layer 171, the second inorganic encapsulation layer 173, the touch buffer layer 181, the first touch insulating layer 183, and the third touch insulating layer 186 may be disposed up to the end of the substrate 101 in the notch non-display area N_NDA, but may not be disposed in the pad area PA. Accordingly, the plurality of pads VSSP, VDDP, DP, and GCP disposed on the fourth insulating layer 106 may be exposed, and the display panel 100_5 may be adhered and electrically connected to the flexible film COF.

Since the gate driving unit GIP (see FIG. 1) is omitted from the non-display area NDA and the pixel gate driving unit GIA is disposed in the display area DA, the non-display area NDA can be reduced, thereby reducing the bezel area and increasing the display area DA.

Even in this case, the light-blocking patterns BP1 and BP3 (see FIG. 5) can block and absorb the light emitted from each pixel PX and traveling in an undesired direction. Even in this case, since the light-blocking pattern BP (see FIG. 5) is disposed on the microlens ML, it is possible to suppress or prevent crosstalk that may occur between images and videos displayed on each pixel PX (see FIG. 5).

A display apparatus according to various embodiments of the present disclosure may be described as follows.

According to example embodiments of the present disclosure, there is provided a display apparatus including a substrate including a display area including a first pixel, a second pixel, and a third pixel, each of which includes a plurality of sub-pixels, and a non-display area around the display area, a first microlens corresponding to each of the plurality of sub-pixels of the first pixel on the substrate, a third microlens corresponding to each of the plurality of sub-pixels of the third pixel on the substrate, a first light-blocking pattern on a surface of the first microlens, and a third light-blocking pattern on a surface of the third microlens, in which each of the first microlens and the third microlens includes a first part located at a first side with respect to a division line, and a second part located at a second side that is a side opposite to the first side, the first light-blocking pattern is disposed on the first part of the first microlens, and the third light-blocking pattern is disposed on the second part of the third microlens.

According to various embodiments of the present disclosure, the first light-blocking pattern may be disposed directly on the first part, and the third light-blocking pattern may be disposed directly on the second part.

According to various embodiments of the present disclosure, the display apparatus may further include a lens protective layer on the first microlens and the third microlens, in which the surface of the first microlens exposed by the first light-blocking pattern may come into contact with the lens protective layer, and the surface of the third microlens exposed by the third light-blocking pattern may come into contact with the lens protective layer.

According to various embodiments of the present disclosure, the display apparatus may further include the second microlens corresponding to each of the plurality of sub-pixels of the second pixel, in which the entire surface of the second microlens may come into contact with the lens protective layer.

According to various embodiments of the present disclosure, the second pixel may be disposed between the first pixel and the third pixel.

According to various embodiments of the present disclosure, the display apparatus may further include a light-emitting part between the substrate and the first microlens, in which the light-emitting part may include an anode electrode, an organic layer between the anode electrode and the first microlens, and a cathode electrode between the organic layer and the first microlens.

According to various embodiments of the present disclosure, the display apparatus may further include a bank disposed between the anode electrode and the cathode electrode, in which the bank may define a first light-emitting area of the first pixel and a third light-emitting area of the third pixel, in which the first light-emitting area may include a first center and the third light-emitting area may include a third center, in which the first center may be misaligned with a division line of the first microlens and the third center may be misaligned with a division line of the third microlens.

According to various embodiments of the present disclosure, the division line of the first microlens may be located at a second side with respect to the first center, and the division line of the third microlens may be located at a first side with respect to the third center.

According to various embodiments of the present disclosure, the display apparatus may further include a protective layer between the substrate and the light-emitting part, in which an upper surface of the anode electrode of the first pixel and an upper surface of the anode electrode of the third pixel may be tilted with respect to an upper surface of the protective layer.

According to various embodiments of the present disclosure, the upper surface of the anode electrode of the first pixel and the upper surface of the anode electrode of the third pixel may be tilted toward opposite sides.

According to various embodiments of the present disclosure, the upper surface of the anode electrode of the first pixel may be tilted toward the first microlens, and the upper surface of the anode electrode of the third pixel may be tilted toward the third microlens.

According to various embodiments of the present disclosure, the display apparatus may further include a pad area, and a low-potential voltage line and a high-potential voltage line that are electrically connected to the pad area, in which, in the non-display area under the display area, the high-potential voltage line may be located between the low-potential voltage line and the display area.

According to various embodiments of the present disclosure, the low-potential voltage line may surround the display area.

According to various embodiments of the present disclosure, the non-display area at a left or right of the display area may further include a gate driving unit between the low-potential voltage line and the display area.

According to various embodiments of the present disclosure, the display apparatus may further include a pixel gate driving unit located in the display area, and a gate control line electrically connecting the pad area to the pixel gate driving unit, in which the gate control line may be located between the low-potential voltage line and the display area.

According to embodiments of the present disclosure, there is provided a display apparatus including a substrate including a display area including a first pixel, a second pixel, and a third pixel, each of which includes a plurality of sub-pixels, and a non-display area around the display area, a thin film transistor disposed on the substrate, a protective layer disposed on the thin film transistor, a light-emitting part disposed on the protective layer and including an anode electrode, an organic layer, and a cathode electrode, an encapsulation layer disposed on the light-emitting part, a microlens disposed on the encapsulation layer and including a first microlens corresponding to the first pixel and a third microlens corresponding to the third pixel, and a light-blocking pattern including a first light-blocking pattern disposed on the first microlens and a third light-blocking pattern disposed on the third microlens, in which each of the first microlens and the third microlens includes a first part located at a first side with respect to a division line that divides the first microlens and the third microlens, and a second part located at a second side that is a side opposite to the first side, the first light-blocking pattern is disposed on the first part, and the third light-blocking pattern is disposed on the second part.

According to various embodiments of the present disclosure, the first light-blocking pattern may be disposed directly on the first part, and the third light-blocking pattern may be disposed directly on the second part.

According to various embodiments of the present disclosure, the second pixel may be disposed between the first pixel and the third pixel.

According to various embodiments of the present disclosure, the display apparatus may further include a bank disposed between the anode electrode and the cathode electrode and defining a light-emitting area of each of the first pixel, the second pixel, and the third pixel, in which an area of the light-emitting area of the second pixel may be greater than an area of the light-emitting area of the first pixel and an area of the light-emitting area of the third pixel.

According to various embodiments of the present disclosure, the display apparatus may further include a second microlens corresponding to the second pixel, in which an area of the second microlens may be greater than an area of the first microlens and an area of the third microlens.

Although various example embodiments have been described above with reference to the accompanying drawings, those skilled in the art to which the present disclosure pertains will be able to understand that the above-described technical configuration can be carried out in other specific forms without changing the technical idea or essential features thereof. Accordingly, it should be understood that the above-described example embodiments are illustrative and not restrictive in all respects. In addition, the protected scope of the disclosure may be determined by the appended claims and their equivalents rather than detailed description. In addition, the meaning and scope of the claims and all changed or modified forms derived from the equivalent concept thereof should be construed as being included in the scope of the present disclosure.

### DESCRIPTION OF REFERENCE NUMERALS

1: display apparatus
100: display panel
101: substrate
NCP: notch
DA: display area
NDA: non-display area
NDA1: first non-display area
NDA2: second non-display area
N_NDA: notch non-display area
E_NDA: extension non-display area
PA: pad area
SP: sub-pixel
EA: light-emitting area
NEA: non-light-emitting area
ML: microlens
BP: light-blocking pattern
150: light-emitting part
170: encapsulation part

What is claimed is:

1. A display apparatus, comprising:
a substrate including a display area including a first pixel, a second pixel, and a third pixel, each of which includes a plurality of sub-pixels, and a non-display area around the display area;
a first microlens corresponding to each of the plurality of sub-pixels of the first pixel on the substrate;
a third microlens corresponding to each of the plurality of sub-pixels of the third pixel on the substrate;
a first light-blocking pattern on a surface of the first microlens; and
a third light-blocking pattern on a surface of the third microlens,
wherein each of the first microlens and the third microlens includes a first part located at a first side, and a second part located at a second side that is a side opposite to the first side with respect to a division line,
wherein the first light-blocking pattern is disposed on the first part of the first microlens, and
wherein the third light-blocking pattern is disposed on the second part of the third microlens.

2. The display apparatus of claim 1, wherein the first light-blocking pattern is disposed directly on the first part, and the third light-blocking pattern is disposed directly on the second part.

3. The display apparatus of claim 1, further comprising a lens protective layer on the first microlens and the third microlens,
wherein a surface of the first microlens exposed by the first light-blocking pattern comes into contact with the lens protective layer, and
wherein a surface of the third microlens exposed by the third light-blocking pattern comes into contact with the lens protective layer.

4. The display apparatus of claim 3, further comprising a second microlens corresponding to each of the plurality of sub-pixels of the second pixel,
wherein an entire surface of the second microlens comes into contact with the lens protective layer.

5. The display apparatus of claim 1, wherein the second pixel is disposed between the first pixel and the third pixel.

6. The display apparatus of claim 1, further comprising a light-emitting part between the substrate and the first microlens,
wherein the light-emitting part includes an anode electrode, an organic layer between the anode electrode and the first microlens, and a cathode electrode between the organic layer and the first microlens.

7. The display apparatus of claim 6, further comprising a bank disposed between the anode electrode and the cathode electrode,
wherein the bank defines a first light-emitting area of the first pixel and a third light-emitting area of the third pixel,
wherein the first light-emitting area includes a first center, and the third light-emitting area includes a third center, and
wherein the first center is misaligned with a division line of the first microlens, and the third center is misaligned with a division line of the third microlens.

8. The display apparatus of claim 7, wherein the division line of the first microlens is located at the second side with respect to the first center, and
wherein the division line of the third microlens is located at the first side with respect to the third center.

9. The display apparatus of claim 8, further comprising a protective layer between the substrate and the light-emitting part,
wherein an upper surface of the anode electrode of the first pixel and an upper surface of the anode electrode of the third pixel are tilted with respect to an upper surface of the protective layer.

10. The display apparatus of claim 9, wherein the upper surface of the anode electrode of the first pixel and the upper surface of the anode electrode of the third pixel are tilted to opposite sides.

11. The display apparatus of claim 10, wherein the upper surface of the anode electrode of the first pixel is tilted toward the first microlens, and the upper surface of the anode electrode of the third pixel is tilted toward the third microlens.

12. The display apparatus of claim 1, further comprising: a pad area; and a low-potential voltage line and a high-potential voltage line that are electrically connected to the pad area,
wherein, in the non-display area under the display area, the high-potential voltage line is located between the low-potential voltage line and the display area.

13. The display apparatus of claim 12, wherein the low-potential voltage line surrounds the display area.

14. The display apparatus of claim 12, wherein the non-display area located at a left or right of the display area includes a gate driving unit between the low-potential voltage line and the display area.

15. The display apparatus of claim 12, further comprising:
a pixel gate driving unit located in the display area; and a gate control line electrically connecting the pad area to the pixel gate driving unit,
wherein the gate control line is located between the low-potential voltage line and the display area.

16. A display apparatus, comprising:
a substrate including a display area including a first pixel, a second pixel, and a third pixel, each of which includes a plurality of sub-pixels, and a non-display area around the display area;
a thin film transistor disposed on the substrate;
a protective layer disposed on the thin film transistor;
a light-emitting part disposed on the protective layer and including an anode electrode, an organic layer, and a cathode electrode;
an encapsulation layer disposed on the light-emitting part;
a microlens disposed on the encapsulation layer and including a first microlens corresponding to the first pixel and a third microlens corresponding to the third pixel; and
a light-blocking pattern including a first light-blocking pattern disposed on the first microlens and a third light-blocking pattern disposed on the third microlens,
wherein each of the first microlens and the third microlens includes a first part located at a first side with respect to a division line that divides the first microlens and the third microlens, and a second part located at a second side that is a side opposite to the first side,
wherein the first light-blocking pattern is disposed on the first part, and
wherein the third light-blocking pattern is disposed on the second part.

17. The display apparatus of claim 16, wherein the first light-blocking pattern is disposed directly on the first part, and the third light-blocking pattern is disposed directly on the second part.

18. The display apparatus of claim 16, wherein the second pixel is disposed between the first pixel and the third pixel.

19. The display apparatus of claim 16, further comprising a bank disposed between the anode electrode and the cathode electrode and defining a light-emitting area of each of the first pixel, the second pixel, and the third pixel,
wherein an area of the light-emitting area of the second pixel is greater than an area of the light-emitting area of the first pixel and greater than an area of the light-emitting area of the third pixel.

20. The display apparatus of claim 19, wherein the microlens further includes a second microlens corresponding to the second pixel, and
wherein an area of the second microlens is greater than an area of the first microlens and greater than an area of the third microlens.
